(19) United States
(12) Patent Application Publication
(10) Pub. No.: US 2026/0155826 A1
(43) Pub. Date: Jun. 4, 2026

(54) FERROELECTRIC FET BASED CONTEST-SWITCHING FPGA ENABLING DYNAMIC RECONFIGURATION FOR ADAPTIVE DEEP LEARNING MACHINES

(71) Applicant: The Penn State Research Foundation, University Park, PA (US)

(72) Inventors: Yixin Xu, State College, PA (US); Yi Xiao, State College, PA (US); Kai Ni, Notre Dame, IN (US); Vijaykrishnan Narayanan, State College, PA (US); Zijian Zhao, Notre Dame, IN (US)

(21) Appl. No.: 18/962,629

(22) Filed: Nov. 27, 2024

Related U.S. Application Data
(60) Provisional application No. 63/603,838, filed on Nov. 29, 2023.

(51) Int. Cl. H03K 19/17728; H03K 19/17704; H03K 19/17736; H03K 19/1776

(52) U.S. Cl. CPC H03K 19/17728; H03K 19/17704; H03K 19/17736; H03K 19/1776

(57) ABSTRACT

Embodiments can relate to a field-programmable gate array having a platform including an interconnect network of configuration blocks. The configuration blocks can include one or more configurable logic blocks (CLBs), one or more connection blocks (CBs), and one or more switch blocks (SBs). Each CLB can include a look-up table (LUT) cell configured to perform a logic operation. Each CB can be configured to connect one or more CLBs to the interconnection network. Each SB can be configured to connect routes between the configuration blocks. One or more or the CBs can include a 1FeFET for a single configuration, one or more of the CBs can include a 2T-2FeFET for a multiple configuration, one or more of the CLBs can include a 1FeFET LUT cell for a single configuration, or one or more of the CLBs can include two 1FeFET LUT cells for a multiple configuration.

### CROSS-REFERENCE TO RELATED APPLICATIONS

This patent application is related to and claims the benefit of U.S. provisional Ser. No. 63/603,838 , filed on Nov. 29, 2023, the entire contents of which is incorporated herein by reference,

### STATEMENT REGARDING FEDERALLY SPONSORED RESEARCH OR DEVELOPMENT

This invention was made with government support under Grant No. DE-SC0021118 awarded by the Department of Energy, under Grant Nos. 2132918 and 2008365 awarded by the National Science Foundation and under Grant No. W911NF-21-1-0341 awarded by the United States Army/ARO. The Government has certain rights in the invention.

### FIELD OF THE INVENTION

Embodiments relate to a field effect transistor based contest-switching field programable gate array configured for dynamic reconfiguration. For instance, an exemplary Field Programmable Gate Array (FPGA) disclosed herein can include two local copies of primitives placed in parallel to facilitate loading of arbitrary configuration without interrupting the active configuration execution—e.g., one configuration can be loaded on the fly while the other configuration is under execution.

### BACKGROUND OF THE INVENTION

Field Programmable Gate Array is widely used in acceleration of deep learning applications because of its reconfigurability, flexibility, and fast time-to-market. However, conventional FPGA suffers from the tradeoff between chip area and reconfiguration latency, making efficient FPGA accelerations that require switching between multiple configurations still elusive.

### SUMMARY OF THE INVENTION

Embodiments can relate to a field-programmable gate array (FPGA). The FPGA can have a platform including an interconnect network of configuration blocks. The configuration blocks can include one or more configurable logic blocks (CLBs), each CLB including a look-up table (LUT) cell configured to perform a logic operation. The configuration blocks can include one or more connection blocks (CBs), each CB configured to connect one or more CLBs to the interconnection network. The configuration blocks can include one or more switch blocks (SBs), each SB configured to connect routes between the configuration blocks. One or more or the CBs can include a 1FeFET for a single configuration. One or more of the CBs can include a 2T-2FeFET for a multiple configuration. One or more of the CLBs can include a 1FeFET LUT cell for a single configuration. One or more of the CLBs can include two 1FeFET LUT cells for a multiple configuration.

In some embodiments, the platform can be a substrate.

In some embodiments, the FPGA can include a configuration memory in connection with the one or more or the CBs and the one or more or the SBs.

In some embodiments, the one or more CBs can include only a single 1FeFET for the single configuration.

In some embodiments, the 1FeFET of the one or more CBs can include a FeFET having a source connected to an input, a drain connected to an output, and a gate connected to a word line (WL).

In some embodiments, the 2T-2FeFET architecture can include two parallel branches.

In some embodiments, the 2T-2FeFET architecture can include: a first MOSFET having a source (S1), a gate (G1), and a drain (D1); a first FeFET having a source (S2), a gate (G2), and a drain (D2); a second MOSFET having a source (S3), a gate (G3), and a drain (D3); a second FeFET having a source (S4), a gate (G4), and a drain (D4). Each of S1 and S3 can be connected to an input. D1 can be connected to S2. Each of D2 and D4 can be connected to an output. D3 can be connected to S4.

In some embodiments, the 1FeFET LUT cell for the single configuration can include plural memory cells connected to a multiplexer. High-V_{TH}/low-V_{TH} states of the 1FeFET can facilitate storage of bits ‘1’/‘0’ in the plural memory cells.

In some embodiments, the two 1FeFET LUT cells for the multiple configuration can include a first 1FeFET LUT cell having plural memory cells connected to a first multiplexer, wherein high-V_{TH}/low-V_{TH} states of the 1FeFET facilitates storage of bits ‘1’/‘0’ in the plural memory cells. The two 1FeFET LUT cells for the multiple configuration can include a second 1FeFET LUT cell having plural memory cells connected to a second multiplexer, wherein high-VTH/low-VTH states of the 1FeFET facilitates storage of bits ‘1’/‘0’ in the plural memory cells. The one or more of the CLBs can include a third multiplexer. The third multiplexer can be connected to each of the first multiplexer and the second multiplexer.

As will be demonstrated from the disclosure presented herein, embodiments can provide context-switching FPGA enabling dynamic reconfiguration to break the tradeoff experienced by conventional techniques. This can be done with no additional area cost and lower power consumption compared with conventional static random-access memory (SRAM) based designs, which can hide the reconfiguration time behind the execution time. Leveraging the intrinsic transistor structure and non-volatility of ferroelectric FET (FeFET), compact FPGA primitives are demonstrated and experimentally verified, including 1FeFET look-up table (LUT) cell, 1FeFET routing cell for connection blocks (CBs) and switch boxes (SBs).

An exemplary embodiment supports dynamic reconfiguration by placing two local copies of primitives in parallel, which enables loading of arbitrary configuration without interrupting the active configuration execution. As will be explained in more detail, with a parallel 2T-2FeFET branch, one configuration can be loaded on the fly while the other configuration is under execution, leading to dynamic reconfiguration of the FPGA.

A comprehensive evaluation of this exemplary set-up shows that compared with the SRAM based FPGA, embodiments of the dynamic reconfiguration design presented herein shows 63.0%/74.7% reduction in LUT/CB area and 82.7%/53.6% reduction in CB/SB power consumption with minimal penalty in the critical path delay (9.6%). Experiments further evaluate the performance of the inventive FPGA in implementing the Super-Sub network model leveraging its context-switching capability, which shows up to 3.0% improvement in classification accuracy. Experiments further evaluate the timing performance of our design over conventional FPGA in various application scenarios. In one scenario that users switch between two preloaded configurations, the inventive design yields significant time saving by 78.7% on average. In the other scenario of implementing multiple configurations with dynamic reconfiguration, the inventive design offers time saving of 20.3% on average. The inventive design provides an efficient solution to bridge the gap and makes FPGA more competitive in accelerating complex deep learning applications.

Further features, aspects, objects, advantages, and possible applications of the present invention will become apparent from a study of the exemplary embodiments and examples described below, in combination with the Figures, and the appended claims.

### BRIEF DESCRIPTION OF THE DRAWINGS

The above and other objects, aspects, features, advantages and possible applications of the present innovation will be more apparent from the following more particular description thereof, presented in conjunction with the following drawings. Like reference numbers used in the drawings may identify like components.

FIG. 1A shows a conventional SRAM-based FPGA.

FIG. 1B shows a SRAM-based FPGA supporting partial reconfiguration.

FIG. 1C shows an exemplary FeFET-based context switching FPGA supporting dynamic reconfiguration.

FIG. 1D shows an example of a deep learning network: Two-stage Super-Sub network, where at first the superclass ‘Dog’ is identified and then the subclass ‘Husky’ is identified.

FIG. 1E shows how a conventional FPGA incurs area overhead or significant reconfiguration latency. This figure shows two main approaches of implementing the Super-Sub network in conventional FPGA.

FIG. 1F shows an approach using an exemplary embodiment disclosed herein to provides fast reconfiguration speed and compact solutions.

FIG. 2A shows primitive FPGA components with dual configuration support.

FIG. 2B shows existing memory technology-based single configuration switch implementations.

FIG. 2C shows exemplary FeFET-based switches. In the multi-configuration switch, dynamic reconfiguration is achieved by turning the pass transistors on/off to select active branch/reconfigure branch.

FIG. 2D shows an exemplary FeFET-based LUT for dual-configuration. This exemplary embodiment includes two single configuration LUTs and one extra multiplexer for selecting proper configuration when needed.

FIGS. 3A-3J show experimental verification of an exemplary LUT cell operation. FIG. 3A shows a TEM and FIG. 3B shows a schematic cross section of an exemplary LUT cell. FIG. 3C shows I_{D}-V_{G} characteristics for FeFET measured after ±4 V, 1 μs write pulses. FIG. 3D shows switching dynamics of FeFET under different pulse amplitudes and pulse widths. FIGS. 3E and 3F show operations of an exemplary LUT cell for storage with bit ‘0’/‘1’ by exploiting the dynamic LVT/HVT programming capability. FIG. 3G shows an exemplary k-bit LUT. FIG. 3H shows an experimental setup of functional verification of an exemplary LUT cell operation. FIG. 3I shows experimental waveforms of exemplary LUT cells. FIG. 3J shows circuitry of an exemplary LUT array or multiple configurations.

FIGS. 4A-4G show experimental verification of a multi-configuration CB operation. FIG. 4A shows an exemplary structure of one 2×2 CB array. FIG. 4B shows that by applying different read gate voltages, the swap between configurations can be achieved. FIG. 4C shows an example waveform applied to set the branch 1/branch 2 to be at the low-V_{TH}/high-V_{TH} states respectively without interrupting normal operation. FIG. 4D shows the circuitry of one CB test unit. FIG. 4E shows experimental transient waveforms of run-time context configuration and switching repeated for 3 cycles. FIGS. 4F and 4G show a zoomed-in programming waveform for branch 1/branch 2 in tests, respectively. The zoomed-in programming waveform is shown due to its small write pulse width.

FIGS. 5A-5C show area comparison and simulation results. FIG. 5A shows area impact of exemplary FeFET LUT cells (storage) and CBs over SRAM based structures. FIG. 5B shows delay and power comparison of main components of an exemplary FPGA based on different memory technologies. FIG. 5C shows critical path delay of different memory technology-based FPGA designs.

FIGS. 6A-6F show application case studies of exemplary multi-configuration FPGAs for different application scenarios. FIG. 6A shows an image classification workflow. FIG. 6B shows dynamic inference for image classification improves the accuracy. FIG. 6C shows a diagram of the experimental setup of the second case study: design preloads two configurations in the FPGA, and then switch between them as needed. FIG. 6D shows a comparison to conventional FPGA, the capability of switching between 2 configurations of our design yields significant time saving varying from 39.0% to 97.5% in an embodiment of the inventive case (in an ideal case, the maximum time saving would be 100%). FIG. 6E shows a diagram illustrating the experimental setup of the third case study: an exemplary FPGA implements and performs three different neural networks using dynamic reconfiguration which achieves operating and reconfiguring simultaneously. FIG. 6F shows switching between 3 neural networks with dynamic reconfiguration offers time saving varying from 2.4% to 37.4% compared to traditional FPGA (in an ideal case, the time saving would be 50%).

FIG. 7 shows a basic structure of FPGA and mechanisms of primitives.

FIG. 8A shows retention of FeFETs at room temperature, FIG. 8B shows retention of FeFETs at 85° C., and FIG. 8C shows endurance characteristics of FeFETs.

FIGS. 9A and 9B shows two potential applications of the inventive FeFET-based context-switching FPGA architecture. FIG. 9A shows the inventive design being used in image classification and to help reduce processing time dramatically for processing a large number of images. FIG. 9B shows that for some large and complex neural networks which cannot completely fit in general FPGA, the inventive FeFET-based context-switching FPGA architecture provides reliable solutions through dynamic reconfiguration.

FIGS. 10A and 10B show a simulation waveform of an exemplary 6-input FeFET LUT. FIG. 10A shows the simulation waveform of select signal in an exemplary 6-input LUT. FIG. 10B shows the simulation waveform of output signal in an exemplary 6-input LUT. The average read delay is around 124 ps.

FIG. 11 illustrates bias conditions for the second step of the two-step programming and the I_{D}-V_{G} characteristics of the low-V_{TH} and high-V_{TH} states and the half-selected cells, W/L=0.5 μm/0.5 μm.

FIGS. 12A-12D show experimental verification of the multi-configuration CB operation when both branches are in the high-V_{TH} states. FIG. 12A shows the circuitry of one CB test unit. FIG. 12B shows the experimental transient waveforms of run-time context configuration and switching repeated for 3 cycles. FIGS. 12C and 12D show the zoomed-in programming waveform for branch 1/branch 2 to the high-V_{TH} state, respectively.

FIGS. 13A-13D show experimental verification of the multi-configuration CB operation when both branches are in the low-V_{TH} states. FIG. 13A shows the circuitry of one CB test unit. FIG. 13B shows the experimental transient waveforms of run-time context configuration and switching repeated for 3 cycles. FIGS. 13A and 13D show the zoomed-in programming waveform for branch 1/branch 2 to the low-V_{TH} state, respectively.

FIGS. 14A-14D show experimental verification of the multi-configuration CB operation when branch 1/branch 2 are in the high-V_{TH}/low-V_{TH} states, respectively. FIG. 14A shows the circuitry of one CB test unit. FIG. 14B shows the experimental transient waveforms of run-time context configuration and switching repeated for 3 cycles. FIGS. 14C and 14D show the zoomed-in programming waveform for branch 1/branch 2 to the high-V_{TH}/low-V_{TH} state, respectively.

FIGS. 15A and 15B show a simulation waveform of a multi-configuration FeFET CB. FIG. 15A shows the simulation waveform of input signal in an embodiment of the inventive multi-configuration FeFET CB. FIG. 15B shows the simulation waveform of output signal in an embodiment of the inventive multi-configuration FeFET CB. The average read delay is around 7.8 ps.

FIG. 16 shows a layout (left panel) of a 6-input LUT and a layout (right panel) of a 2×2 multiconfiguration CB.

FIG. 17 an overview of an exemplary whole FPGA architecture (left panel) and the critical path with delays (right panel) when implementing stereovision0 benchmark through VTR.

FIG. 18A illustrates a case study of dynamically switching layer resources for DNN, 2 systems are used for showing the benefit brought by dynamically switching layer resources. System 1: a Xilinx DPU B1152 core with softmax for accelerating an entire neural network; System 2: a Xilinx DPU B2304 core without softmax for accelerating all but the last layer of a neural network, and a Xilinx DPU B1152 core with softmax for accelerating the last layer of the neural network and softmax layer. FIG. 18B illustrates dynamic switching of layer resources in FPGA yields more throughput in DNN applications. FIG. 18C shows that for some applications that need to be trained more, embodiments of the inventive design still shows significant time saving varying from 11.32% to 88.42%.

### DETAILED DESCRIPTION OF THE INVENTION

The following description is of exemplary embodiments that are presently contemplated for carrying out the present invention. This description is not to be taken in a limiting sense, but is made merely for the purpose of describing the general principles and features of the present invention. The scope of the present invention is not limited by this description.

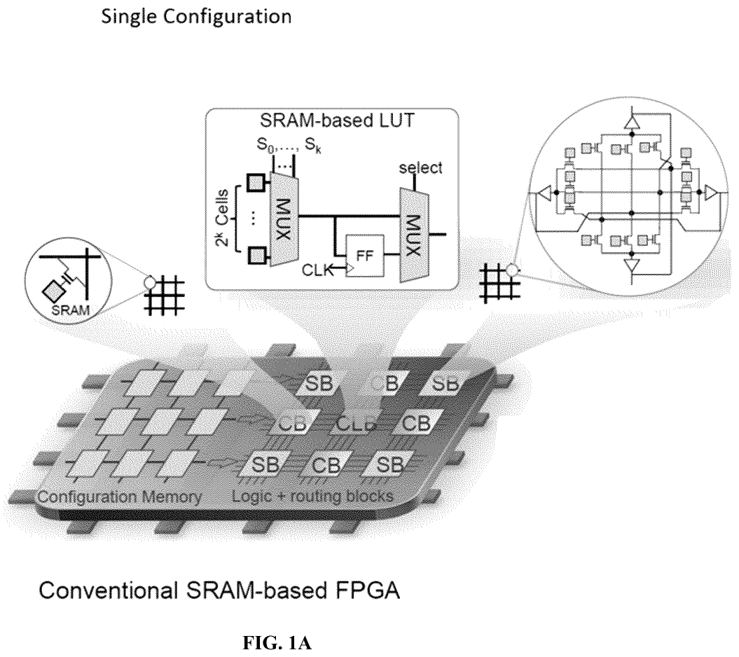

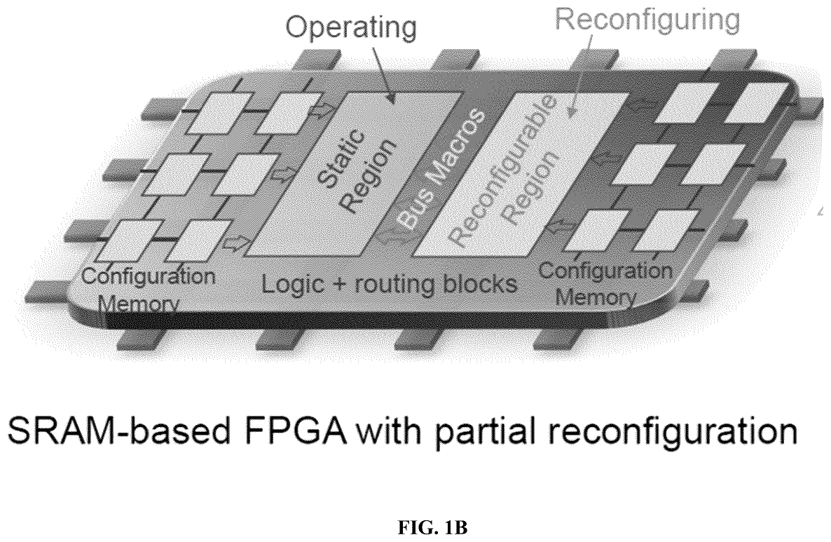

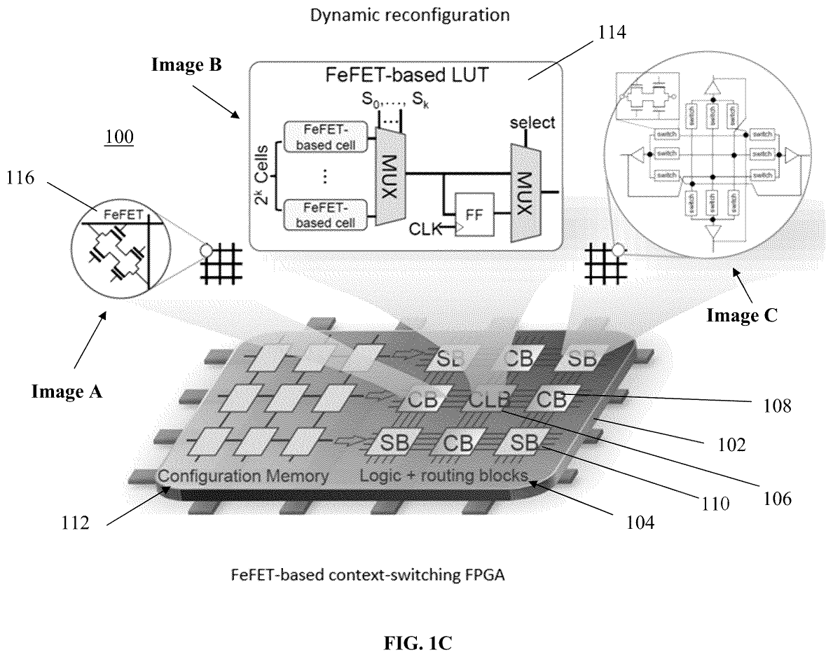

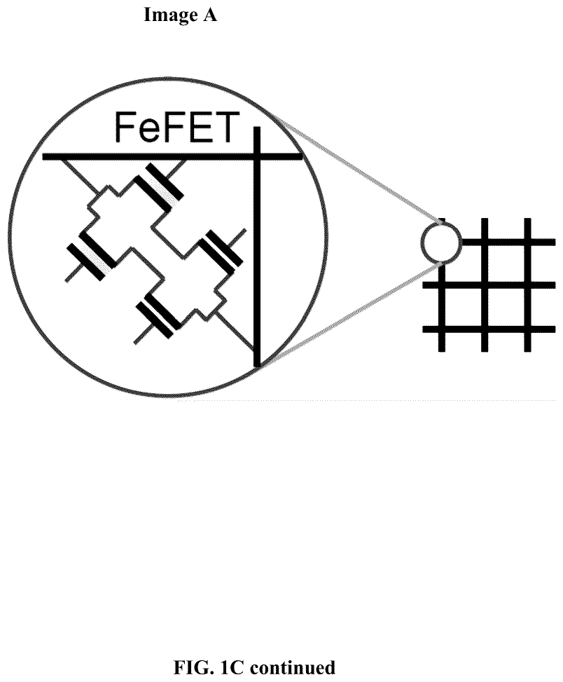

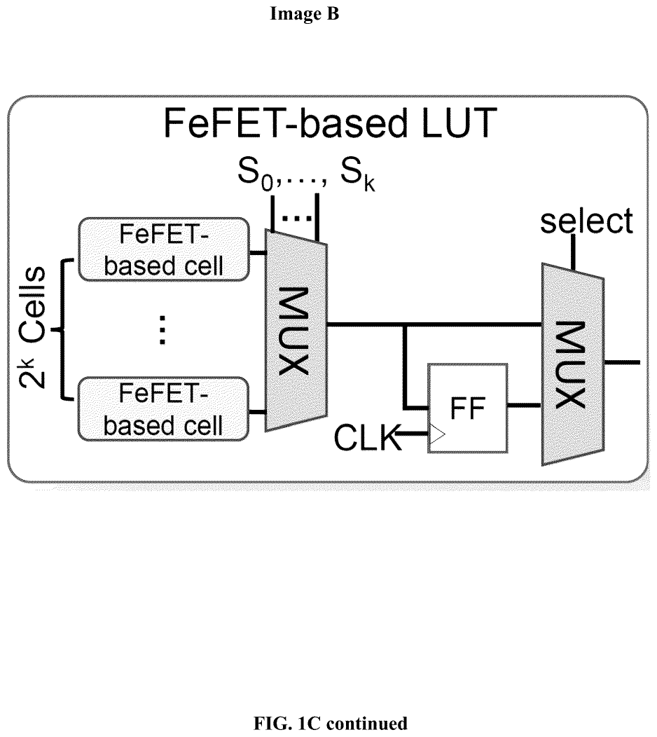

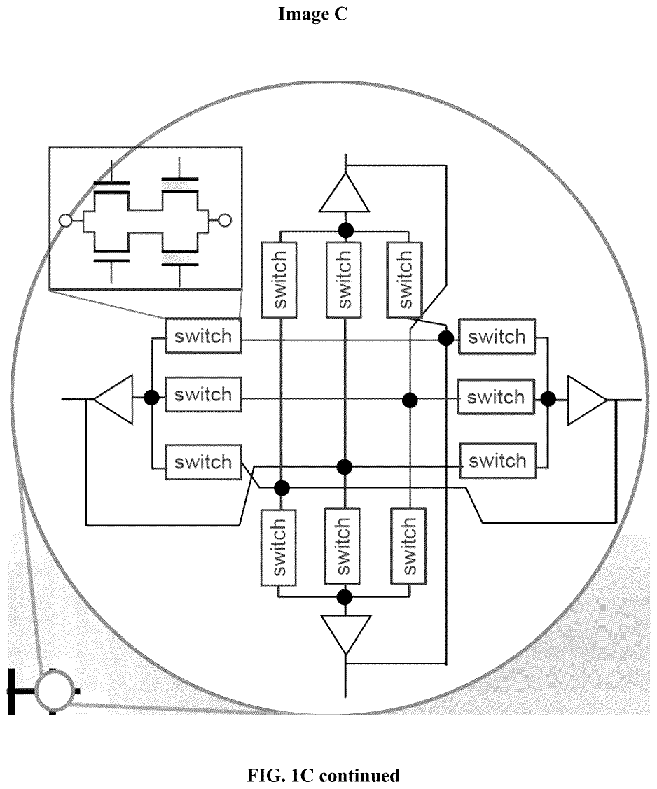

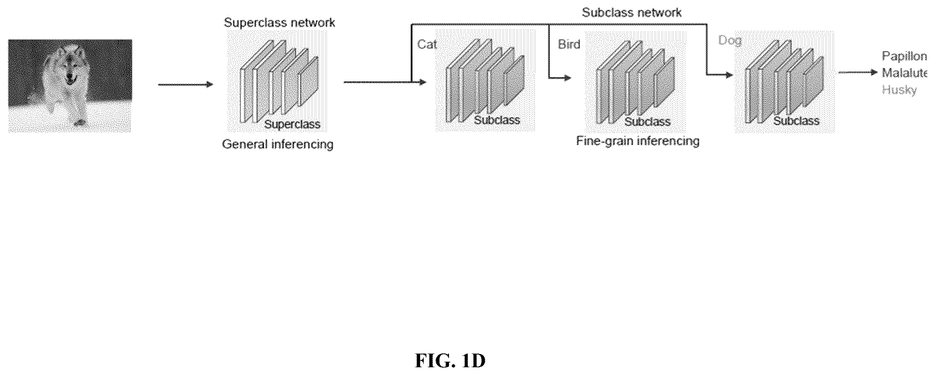

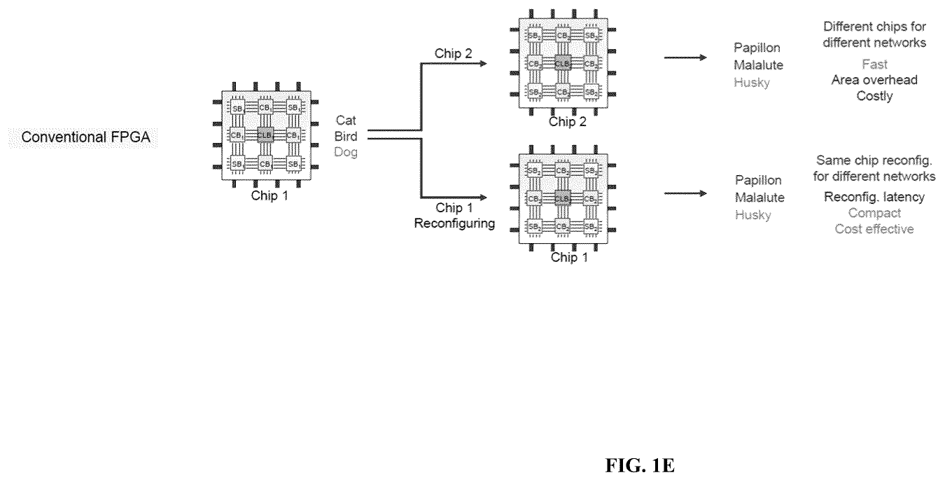

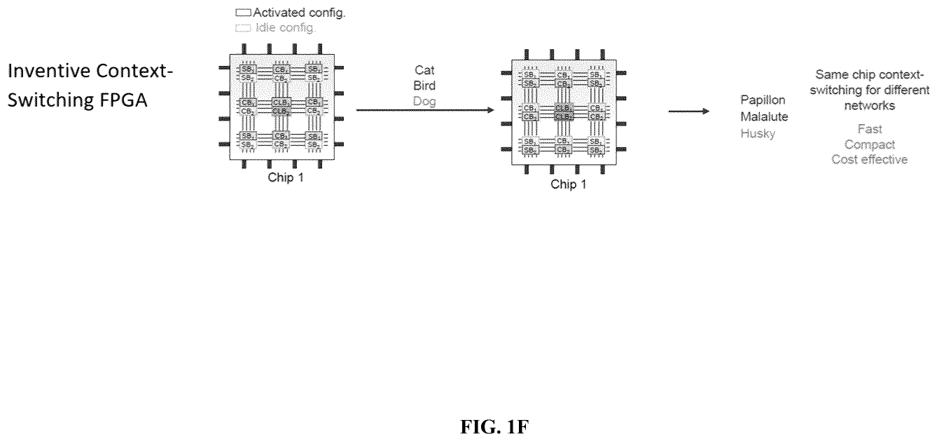

Referring to FIG. 1C, embodiments can relate to a field-programmable gate array (FPGA) 100. The FPGA 100 can include a platform 102. The platform 102 can be a substrate (silicon, germanium, gallium arsenide, indium phosphide, etc.). The platform 102 can provide a base for connectors, circuitry, components, etc. to facilitate formation of one or more interconnect networks, which can be used to generate one or more integrated circuits. For example, the platform 102 can form an interconnect network comprising one or more configuration blocks 104. Configuration blocks 104 of the FPGA 100 can be configured as clusters of basic logic elements. Typical configuration blocks 104 of an FPGA 100 can include one or more of a Configurable Logic Block (CLB) 106, a Connection Block (CB) 108, and a Switch Box (SB) 110. A CLB 106 can act as a basic building block of the FPGA 100, wherein the CLBs 106 can serve as the main computational components of the FPGA 100. CLBs 106 can be responsible for storing and implementing functionality of the circuit the FPGA 100 is connected to or is a part of. CBs 108 can connect CLBs 106 to the interconnection network. SBs 110 can connect routes (e.g., horizontal and vertical routes) between the configuration blocks 104. The FPGA 100 may have a plurality of CLBs 106, a plurality of CBs 108, and a plurality of SBs 110. The CLBs 106, CBs 108, and SBs 110 can work together as logic and routing blocks. For instance, CLBs 106 can be programmed to perform different logic operations, while CBs 108 and SBs 110 can be controlled by configuration bits loaded from one or more configuration memories 112 of the FPGA 100.

One or more of the CLBs 106 can include one or more look-up table (LUT) cells 114. A LUT cell 114 can be configured as a look-up table, in which the stored contents (e.g., configuration bits) are selected by an operator 118 (e.g., a multiplexer—circuit or operating module configured to select one of multiple input signals and forward it to an output line based on digital inputs of one or more select lines of the circuit or operating module). As can be appreciated, a CLB 106 can realize logic functions via one or more LUT cells 114 to process digital operations.

The configuration blocks 104 also allow the FPGA 100 to operate in a configuration. Operating in a configuration involves a process of loading a set of instructions or settings to define the FPGA's 100 functionality. As will be explained herein, embodiments of the FPGA's 100 disclosed herein can provide for dynamic reconfiguration.

An exemplary embodiment of the FPGA 100 includes an interconnect network of configuration blocks 104. The configuration blocks 104 can include one or more CLBs 106. One or more CLBs 106 can include one or more LUT cells 114. One or more of the LUT cells 114 can be configured to perform one or more logic operations. The configuration blocks 104 can include one or more CBs 108. One or more CBs 108 can be configured to connect one or more CLBs 106 to the interconnection network. The configuration blocks 104 can include one or more SBs 110. One or more SBs 110 can be configured to connect routes (e.g., electrical circuit or path routes) between the configuration blocks 104. The FPGA 100 can also have one or more configuration memories 112. One or more configuration memories 112 can be in connection with one or more of the configuration blocks 104 or one or more components (CLBs 106, CBs 108, SBs 110, etc.) of a configuration block 104.

Embodiments of the FPGA 100 can have any number of configuration blocks 104, any number of CLBs 106, any number of CBs 108, any number of SBs 110, any number of LUT cells 114, any number of configuration memories 112, etc. Any component of the FPGA 100 can be the same or different from another component. For instance, the FPGA 100 can have a first configuration block 104, a second configuration block 104, etc. The first configuration block 104 can be structured the same as or different from another configuration block 104. As another example, the FPGA 100 can have a single configuration block 104. Any of the CLBs 106 in the single configuration block 104 can be the same as or different from another CLB 106 in the single configuration block 104. The same can be said for the CBs 108, SBs, LUT cells 114, etc.

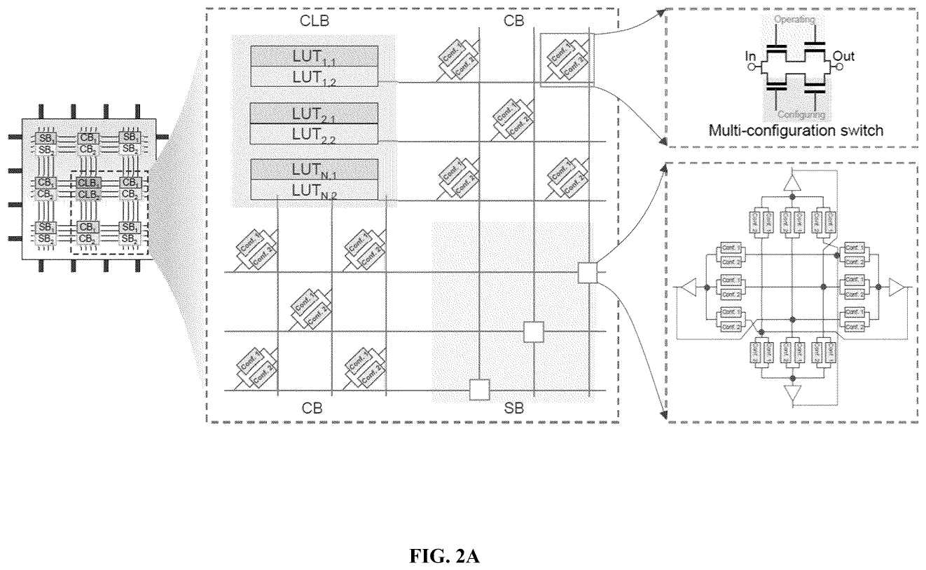

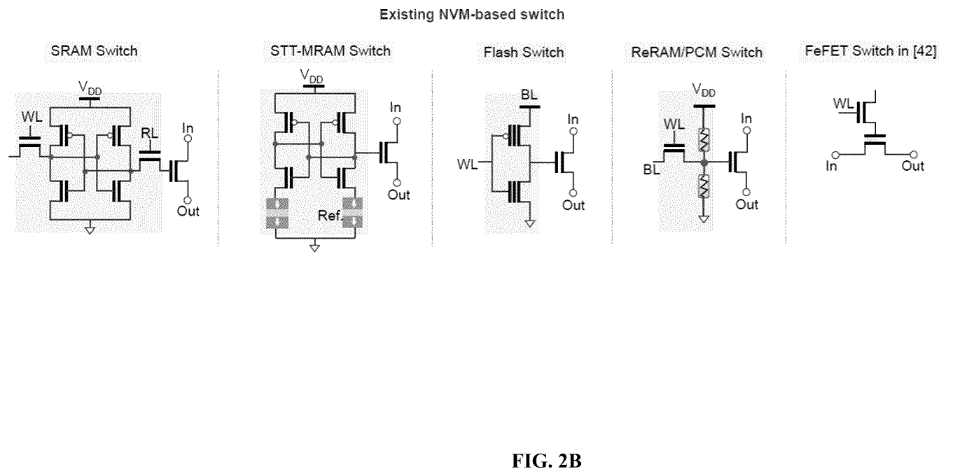

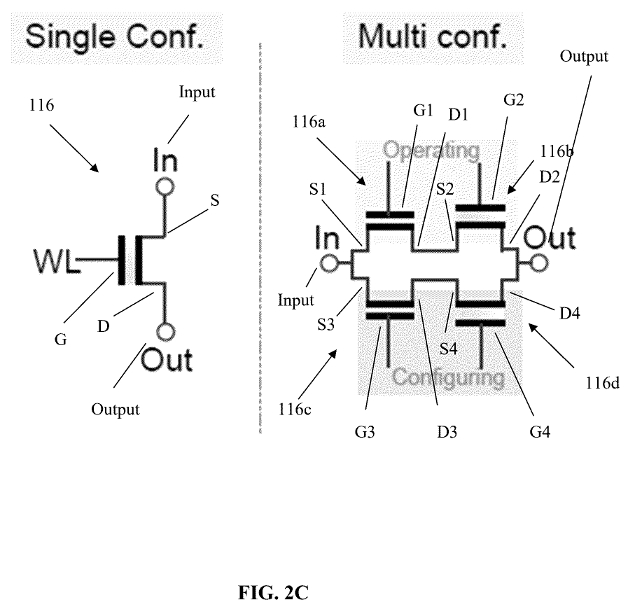

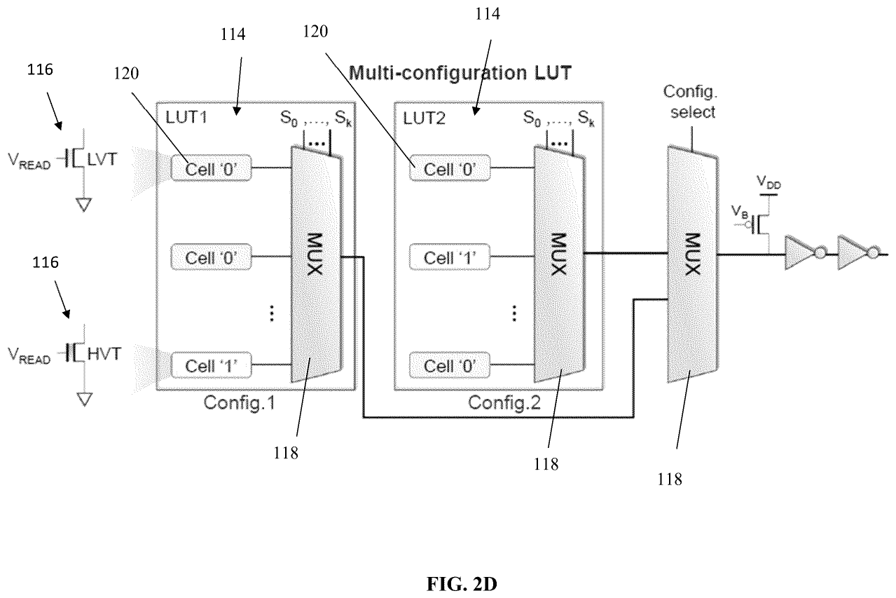

As noted herein, the FPGA's 100 can be configured to provide for dynamic reconfiguration. This can be achieved by one or more of the following:
1. one or more or the CBs 108 can include a 1FeFET 116 for a single configuration of the FPGA 100;
2. one or more of the CBs 108 can include a 2T-2FeFET 116 for a multiple configuration of the FPGA 100;
3. one or more of the CLBs 106 can include a 1FeFET LUT cell 114 for a single configuration of the FPGA 100; or
4. one or more of the CLBs 106 can include two 1FeFET LUT cells 114 for a multiple configuration of the FPGA 100.
Referring to FIG. 2C, it is noted that dynamic reconfiguration of the FPGA 100 can be achieved via the one or more or the CBs 108 including only a single 1FeFET 116 for a single configuration of the FPGA 100—e.g., there only needs to be one 1FeFET 116. With the single 1 FeFET 116 for a single configuration of the FPGA 100, the CB 108 can be structured such that the FeFET 116 has its source(S) connected to an input (Input), its drain (D) connected to an output (Output), and its gate (G) connected to a word line (WL).

For the multiple configuration of the FPGA 100 in which the CB 108 includes a 2T-2FeFET 116, the 2T-2FeFET 116 architecture can be structured to have two parallel branches. For instance, the 2T-2FeFET 116 architecture can include a first MOSFET116a having a source (S1), a gate (G1), and a drain (D1). The 2T-2FeFET 116 architecture can include a first FeFET 116b having a source (S2), a gate (G2), and a drain (D2). The 2T-2FeFET 116 architecture can include a second MOSFET 116c having a source (S3), a gate (G3), and a drain (D3). The 2T-2FeFET 116 architecture can include a second FeFET 116d having a source (S4), a gate (G4), and a drain (D4). Each of S1 and S3 can be connected to an input (Input). D1 can be connected to S2. Each of D2 and D4 can be connected to an output (Output). D3 can be connected to S4.

Referring to FIG. 2D, for the single configuration of the FPGA 100 in which the CLB 106 includes 1FeFET LUT cell 114, the 1FeFET LUT cell 114 can include plural memory cells 120 connected to a multiplexer 118. High-V_{TH}/low-V_{TH} states of the 1FeFET 116 can facilitate storage of bits ‘1’/‘0’ in the plural memory cells 120.

For the multiple configuration of the FPGA 100 in which the CLB 106 includes the two 1FeFET LUT cells 114, a first 1FeFET LUT cell can have plural memory cells 120 connected to a first multiplexer 118, wherein high-V_{TH}/low-V_{TH} states of the 1FeFET facilitates storage of bits ‘1’/‘0’ in the plural memory cells 120. A second 1FeFET LUT cell 114 can have plural memory cells 120 connected to a second multiplexer 118, wherein V_{TH}/low-V_{TH} states of the 1FeFET facilitates storage of bits ‘1’/‘0’ in the plural memory cells. The CLB 106 an include a third multiplexer 118. The third multiplexer 118 can be connected to each of the first multiplexer 118 and the second multiplexer 118.

### EXAMPLES

The following disclosure discusses exemplary implementations and test data related to the same.

Deep neural networks (DNNs) have dominated artificial intelligent (AI) applications due to their cutting edge performance in a wide range of applications in many domains, such as image classification, object detection, and natural language processing. However, with more sophisticated models and more voluminous data to process, these DNN workloads are becoming more compute-intensive and data-intensive, requiring hardware accelerators to achieve lower latency, higher throughput, and higher energy efficiency. FPGA devices, with the capabilities of flexible reconfiguration for arbitrary logic functions while maintaining high performance, are gaining popularity as accelerators for such complex deep learning applications. The reconfigurability of FPGA is enabled by its unique architecture, as illustrated in FIG. 1A, which consists of a sea of configuration logic blocks (CLBs), CBs, SBs, configuration memory, and I/O blocks. In particular, CLBs are the main components that can be programmed to perform different logic operations and CBs and SBs are controlled by configuration bits loaded from the configuration memory. A variety of routing networks can be achieved through loading different configuration bits. Above all, FPGA's aforementioned properties including reconfigurability, flexibility, high performance, and fast time-to-market makes it a promising choice for DNN accelerators.

As a concrete and highly important example of DNN acceleration on FPGA, a two-stage Super-Sub network is adopted for image classification. In this model, a superclass is first inferred using a generalist superclass-level network and the network output is then passed to a specialized network for final subclass-level classification. In this way, the overall classification accuracy has been proved to increase over that of common inference methods when evaluating on the “uperclassing ImageNet dataset”, which is a subset of ImageNet and consists of 10 superclasses, each containing 7-116 related subclasses (e.g., 52 bird types, 116 dog types) (12). FIG. 1D shows one specific example of this framework. In the first stage, the superclass ‘Dog’ is identified by the generalist superclass network. Then, fine-gain inference in the subclass network is performed in the second stage and outputs the final result ‘Husky’ of the target image.

Numerous hardware accelerators have been proposed to implement DNNs, such as customized application-specific integrated circuits (ASICs), application driven optimization on graphics processing units (GPUs), and FPGAs. However, among these various types of DNN accelerators, FPGA, which can provide more flexibility while maintaining high performance, is particularly suitable for implementing the accelerators of DNNs such as for the Super-Sub network model. FIG. 1E shows two main approaches when considering implementing this Super-Sub network into FPGA. One distinguished feature of the implementation is the requirement of multiple configurations in FPGA to map the superclass and sub networks, respectively. The straightforward approach is to use more than one chips to process different networks (i.e., configurations). As shown in FIG. 1E, Chip 1 is configured to process the general inference task for superclasses, whose outputs are then sent to the Chip 2 which is configured to map the subclass networks to identify the specific subclass. This approach, although fast, incurs penalties in chip area and cost. Another compact and cost-efficient approach is to leverage the reconfiguration capability of FPGA by simply reconfiguring Chip 1 to the subclass network after it finishes execution of the superclass network. In this way, contexts, i.e., FPGA configurations, can be swapped in or out of the FPGA upon the demands of application requirements without the need of additional chips. Therefore, this approach saves the area cost but comes with a penalty in the reconfiguration latency. Above all, although FPGA offers an attractive choice for acceleration of Super-Sub network model (FIG. 1E), an ideal implementation with high area efficiency and low latency is still elusive with current FPGA technologies and architectures.

Many relevant works have explored design options to address the aforementioned issues at different granularity of reconfiguration and from different angles of applications. However, all of them are still limited by the dilemma or might incur other overheads. For example, a full context-switching FPGA was first proposed as a time multiplexer FPGA based on the Xilinx XC4000E FPGA in 1997, where eight configurations of the FPGA are stored in on-chip memory and the contexts can be switched in a single cycle. With pre-loaded contexts, reconfiguration is not needed but it comes with a large area penalty. The more configurations to be supported, the more area overhead to store those configurations. In order to save area while still speeding up the reconfiguration process, dynamic partial reconfiguration appears as another solution to support multiple configurations, by which only a portion of hardware region (called reconfigurable region) can be reconfigured while the remainder is static. Partial reconfiguration brings several advantages over conventional context-switching FPGA, including less reconfiguration time compared to full-region reconfiguration and smaller area with its increased logic density. However, partial reconfiguration only provides a compromised solution between the area cost and the reconfiguration latency, incapable of fundamentally solving the problem. At the end, it is possible to support fine-gain reconfiguration at bit level, as demonstrated by consecutive works on the ‘NATURE’ FPGA architecture to support fine-gain temporal logic folding, which is either based on CMOS (e.g., logic and SRAM) and carbon nanotube random-access memory (NRAM), or based entirely on CMOS circuits. In the former work, NRAM and SRAM work together to support dynamic reconfiguration for temporal logic folding of circuits, which is to realize different logic functions in the same logic elements through dynamic reconfiguration every few cycles, thereby significantly increasing the logic density. In the latter work, the dynamic reconfiguration delay is hidden behind the computation delay through the use of shadow SRAM cells (i.e., two SRAM copies). However, both works suffer from high area cost which is mainly caused by extra NRAM cells and 10T-SRAM cells respectively. Therefore, to date, a context-switching FPGA that can break the trade-off between the area cost and the reconfiguration latency remains elusive and the goal of the inventive techniques disclosed herein to is to bridge the gap.

To mitigate the aforementioned issues in terms of area, latency and power, embodiments can provide for a dynamic context-switching FPGA architecture based on FeFETs which can implement DNN accelerators more efficiently. With joint innovations from technology, circuit, and architecture levels, the inventive design has several advantages over prior context-switching works. Some of the advantages are explained in the next paragraph.

First, from technology's perspective, FeFET is unique that it behaves both as a transistor switch and a nonvolatile memory cell such that FPGA basic logic circuits (e.g., LUTs) and routing elements (e.g., CBs and SBs) can be implemented compactly. Moreover, these FPGA basic elements have no leakage power dissipation because of the non-volatility of FeFET, which hugely reduces the total power consumption of the entire FPGA. Second, from circuit's perspective, exemplary embodiments provide for a CB composed of two parallel branches, which stores two configurations while still consuming much less area than a single configuration SRAM-based CB. Third, embodiments of the FPGA can be dynamically reconfigurable with the capability to load one configuration without interrupting execution of another configuration. As a result, the reconfiguration time can be completely hidden as long as it is smaller than the computation time of the current active configuration. Therefore, the inventive techniques disclosed herein can achieve dynamic context-switching with zero penalty in reconfiguration latency and significant area reduction compared to SRAM-based design, breaking the trade-off between area cost and reconfiguration latency existed in conventional CMOS implementations.

With the inventive context-switching FPGA, the aforementioned Super-Sub network can be efficiently implemented, as shown in FIG. 1F. Considering one case that we are interested in having an accurate classification of one specific superclass (e.g., Dog), the inventive design can perfectly fit in it and reduce the reconfiguration latency. Specifically, these two configurations including superclass network and subclass network can be preloaded into the FPGA. First, the general inference with the superclass network is performed. As long as the output of the general inference is Dog, the configuration corresponding to Dog's subclass network would be activated and executed for further inference. In this way, compared to long reconfiguration time, the switching time is much less or even negligible, which leads to almost zero latency overhead. In addition, the total area cost could also be heavily reduced by leveraging dense FeFETs. Note that the inventive context-switching FPGA enables applications in various domains that need switching between different contexts, beyond the Super-Sub network discussed here. The reconfiguration functionality is especially helpful in various dynamic adaptation applications such as changing communication encoders or decoders on demand to the appropriate protocols, changing the data rates to vary bandwidths, scaling the computation based on available energy needs. Moreover, with no limitation of the number of configurations, our design can also be scaled to implement multiple configurations depending on the demand of applications.

For a deeper look into the design of the inventive context-switching FPGA, details of the architecture and components to support multiple configurations are shown in FIGS. 2A-2D. FIG. 2A shows primitive components of the inventive context-switching FPGA which supports dual configurations, including CLBs, CBs and SBs. For each component, it is controlled by the configuration information stored in configuration memory. By loading the configuration bits, the logic (LUT) and routing elements (CB/SB) can be connected to form a functional circuit to perform the desired computation. In the inventive context-switching FPGA, there are two local copies of each LUT, CB and SB, which corresponds to two configurations. In this way, when one configuration is active for computation, any other configuration can be loaded without interrupting the execution, thereby significantly reducing the reconfiguration latency. In contrast, in conventional context-switching FPGA, they would either require hardware resources for supporting multiple configurations on-chip or require long serial reconfiguration time. To support run-time reconfiguration and reduce the area cost incurred by the need of an extra copy of FPGA primitive components, FeFET technology, due to its programmability, nonvolatility, and compactness, is chosen in this work to implement basic programmable FPGA components such as LUTs, CBs and SBs.

In recent years, the switches in FPGA can be realized with various embedded memory technologies as the basic elements of routing elements (CBs and SBs). FIG. 2B presents existing mainstream memory technology-based single configuration switches including SRAM, spin transfer torque magnetic RAM (STT-MRAM), Flash memory, resistive RAM (ReRAM), phase change memory (PCM) and FeFET. Due to its logic compatibility, superior write and read performance, and excellent reliability, SRAM is the most straightforward memory to use by combining a SRAM cell with an N-type pass transistor. However, SRAM-based switches suffer from two crucial overheads. One is low area density due to its complex cell structure; the other is high leakage power, which accounts for 60%˜70% of total FPGA power dissipation due to long routing tracks. Recently, emerging embedded nonvolatile memory technologies have been actively investigated as promising alternatives to SRAM due to their density, energy, and performance advantages. However, each of them comes with its own challenges. For example, a Flash memory-based switch is nonvolatile and compact, but memory programming is slow (˜ms) and requires a high programming voltage (˜10 volts). Two terminal resistive memories, including ReRAM, PCM, and STT-MRAM, are nonvolatile and dense, but usually require a large conduction current to program the devices, consuming a significant write power. Additionally, the limited on/off resistance ratio (˜100 for ReRAM/PCM and ˜5 for STT-MRAM) usually requires additional circuitry, such as the 1T2R structure for ReRAM/PCM and an even more complex supporting structure for STT-MRAM to realize a single switch.

In this regard, the inventive FPGA architecture adopts FeFETs to implement logic and routing elements. Ever since the discovery of ferroelectricity in doped HfO2, significant progress has been made in the integration of HfO2 based FeFET due to its nonvolatility, high density, large ON/OFF ratio, and excellent CMOS compatibility. In addition, switching of ferroelectric polarization is induced by an applied electric field, rather than a large conduction current, making FeFET a highly energy-efficient nonvolatile memory. Since the ferroelectric film is integrated in the gate stack of a FeFET, when its polarization is set to point at the channel/metal gate, the FeFET threshold voltage (VTH) will be programmed to the low-VTH/high-VTH, respectively, thus realizing a compact nonvolatile routing element. Leveraging this technology, a mixed FeFET/CMOS switch unit (e.g., 1T-1FeFET) has been proposed as a routing element in FPGA, which takes advantage of but does not fully exploit FeFET. In this work, leveraging the intrinsic nonvolatile switch structure of FeFET, the inventive 1FeFET routing switch can be used for single configuration FPGA and a 2T-2FeFET routing switch for dynamic reconfiguration context-switching FPGA, as shown in FIG. 2C, which achieve optimal area efficiency. An important design difference in the inventive FeFET switch compared to the Flash switch and prior FeFET switch, despite their similarities in the device structure, is that the inventive switch can be composed of only one FeFET, which can significantly improve the integration density. The Flash switch requires a pair of n-type and p-type Flash devices controlling one normal NMOS pass transistor. By applying proper biases on WL and BL, only one of the Flash devices would be conducted to turn ON/OFF the pass transistor. The reason why it cannot be replaced with one Flash transistor might be its relatively poor pass gate performance due to its thick gate stack. Compared to Flash devices, FeFET shows great scalability and compatibility with Si CMOS, making a single FeFET feasible as one pass transistor. Moreover, FeFET allows lower operation voltages for both writes and reads. Besides, for the 1T-1FeFET switch, in addition to FeFET, they need an access transistor to coordinate with operation and programming. However, in the inventive FeFET switch design, a novel program mechanism can be leveraged to write through gate and body terminals and program disturb inhibition scheme. In this way, the inventive design can eliminate the access transistor with lower area cost. For the context-switching FPGA, a serial CMOS transistor is added to each branch, which is used to cutoff the branch that is loading a new configuration to minimize the disturb to the other active branch. FIG. 2D shows an exemplary inventive circuit of LUT array for dual configuration. A compact LUT cell can be efficiently implemented using a single FeFET such that the high-VTH/low-VTH states of FeFET stores bit ‘1’/‘0’ for the LUT cell, respectively. Besides, as shown in FIG. 2D, the inventive LUT can support dynamic reconfiguration—when the branch of configuration 1 is operating, the branch of configuration 2 can load new configuration.

### Block Design and Functional Verification

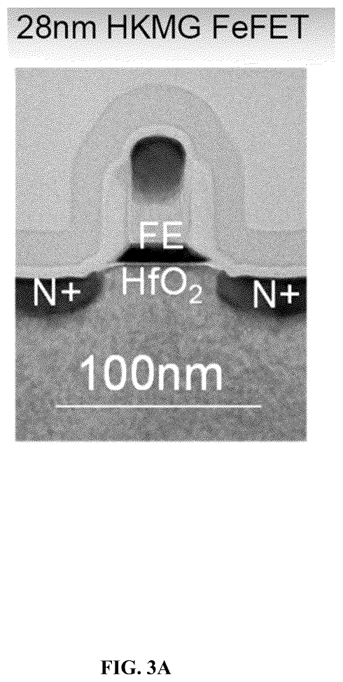

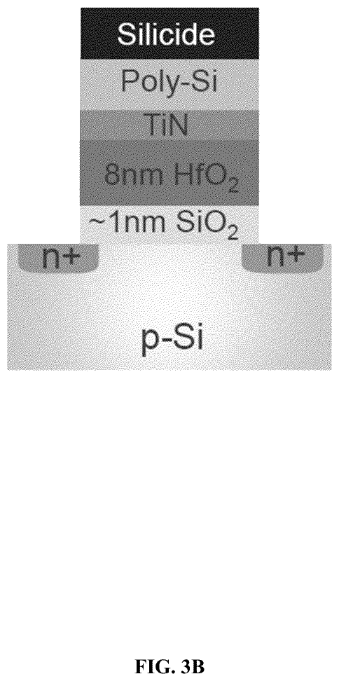

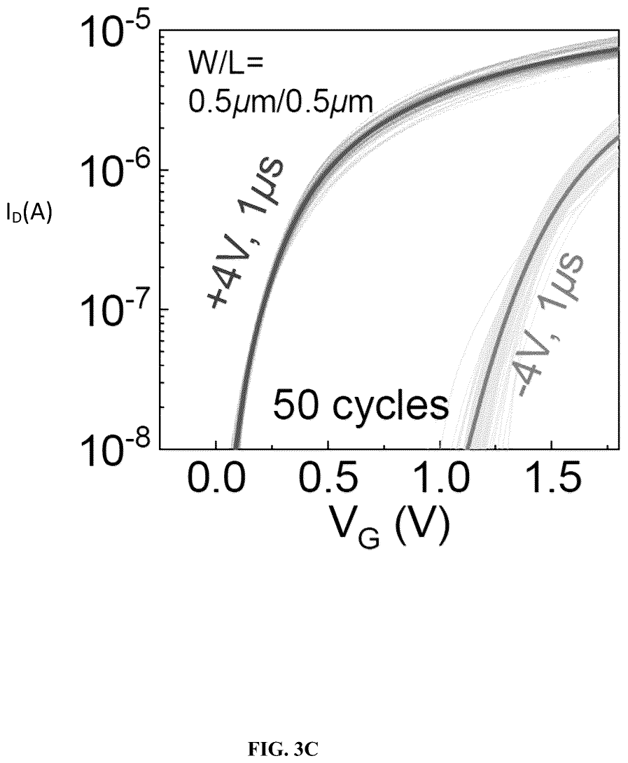

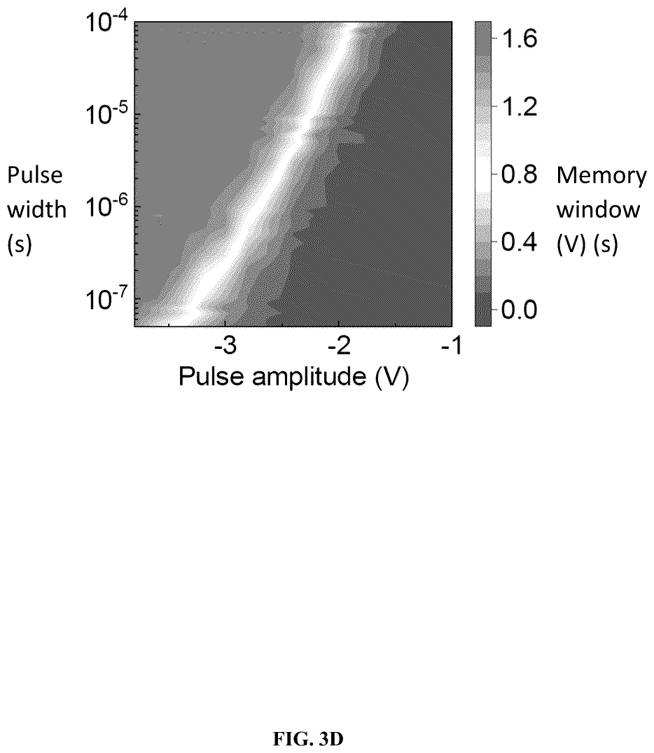

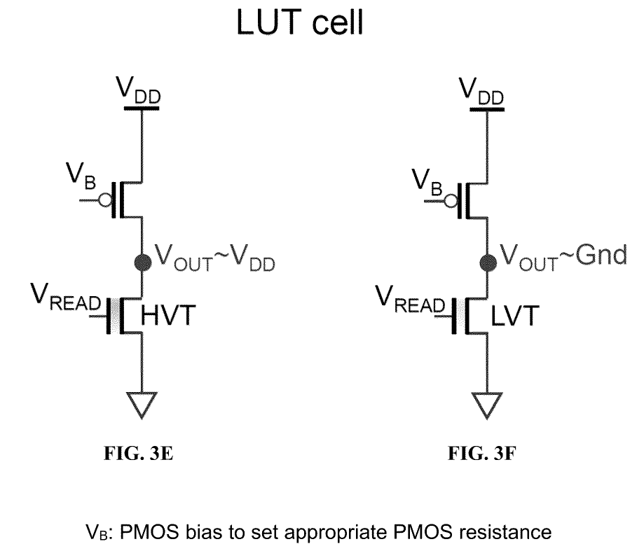

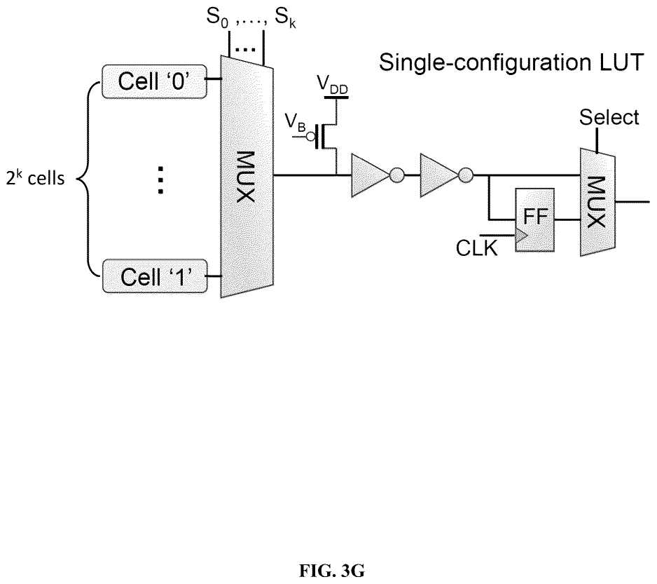

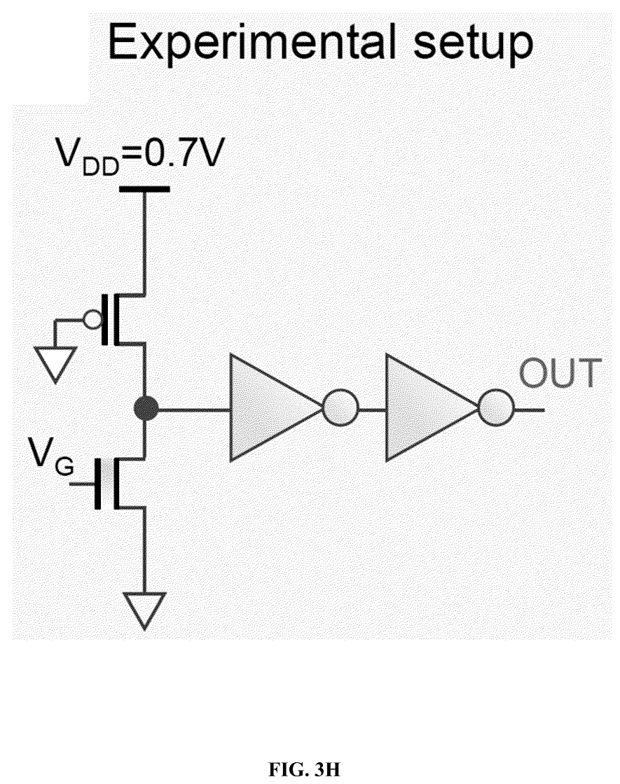

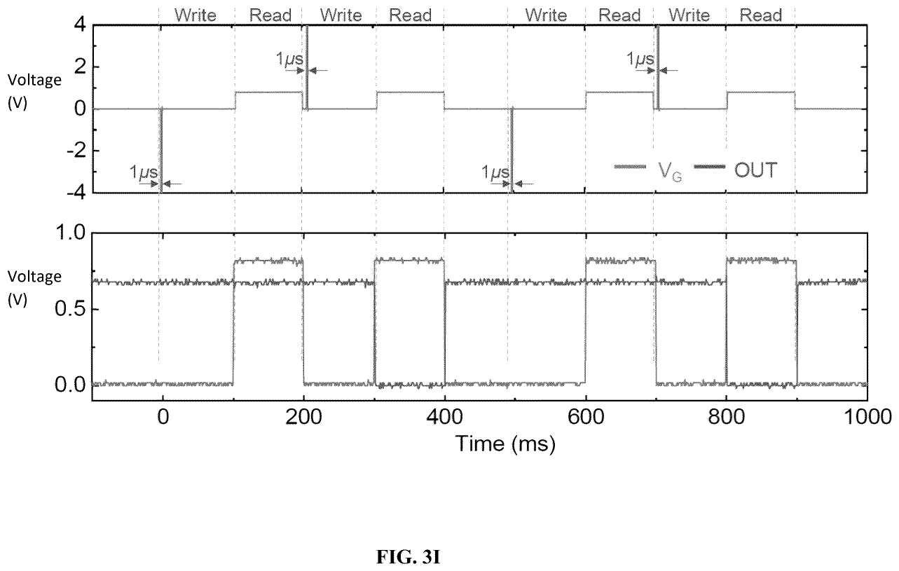

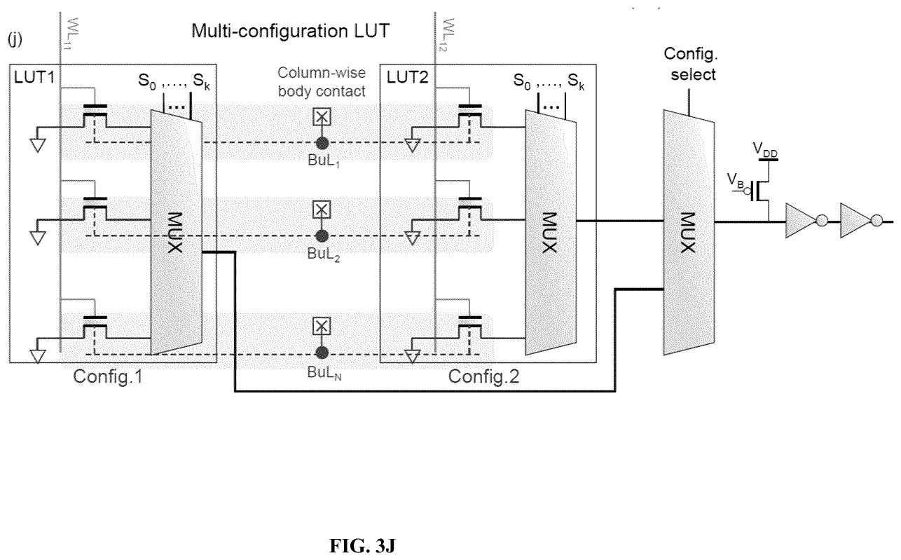

Experimental verification of the inventive LUT and routing elements (CB/SB) for context-switching FPGA is explained. For experimental demonstration, FeFET devices integrated on the 28 nm high-κ metal gate (HKMG) technology are tested. FIGS. 3A and 3B show the transmission electron microscopy (TEM) and schematic cross-section of the device, respectively. The device features an 8 nm thick doped HfO2 as the ferroelectric layer and around 1 nm SiO2 as the interlayer in the gate stack. The FeFET memory performance is characterized by standard pulsed I_{D}-V_{G} measurements after applying ±4 V, 1 μs write pulses on the gate. FIG. 3C shows a memory window about 1.2 V, i.e., the V_{TH} separation between the low-V_{TH} and high-V_{TH} states, which enables a large ON/OFF conductance ratio. It also exhibits a well-tempered cycle-to-cycle variation. FIG. 3D shows the switching dynamics of the FeFET under different pulse amplitudes and pulse widths, which also shows a trade-off between the write speed and pulse amplitude and that it is possible to program FeFET with sub-10 ns with 4V write amplitude. It follows the classic nucleation-limited switching model in the thin film poly-crystalline HfO2, where domain switching is mainly limited by the nucleation process and the nucleation time follows an exponential dependence on the applied electric field. These results suggest that HfO2 based FeFET exhibits a high performance, showing great promise of this technology in many applications including the context-switching FPGA in this work.

FIGS. 3E-3F show the operation principle of exemplary LUT cells that store a bit ‘1’ and ‘0’, respectively. Each cell consists of one single FeFET and one PMOS transistor, where the PMOS is shared among all the cells and is part of the sense amplifier used to convert the read current to logic voltage levels. The bit ‘1’ and ‘0’ is stored by programming the FeFET into the high-V_{TH} and low-V_{TH} state, respectively. Then in the LUT read mode, the stored bit can be read by asserting appropriate read voltage, V_{READ}, to the gate terminal of the FeFET, as shown in FIG. 3E. Due to the large ON/OFF resistance ratio of FeFET at V_{READ}, the output voltage will be close to V_{DD} and ground for bit ‘1’ and ‘0’, respectively. This is achieved by choosing an appropriate PMOS gate bias (V_{B}) such that its resistance is between the FeFET high-V_{TH} and low-V_{TH} states, thereby setting the output voltage rail-to-rail. FIG. 3G demonstrates the main structure of the single configuration LUT integrated with 2k FeFET-based bitcells (Cell ‘0’/Cell ‘1’), different logic functions can be successfully achieved by applying different combinations of select signals. In this structure, a sense amplifier composed of one pull-up PMOS transistor and two inverters is used for converting FeFET read current to voltage and amplifying the output voltage to full swing. The LUT cell operation is then verified in experiment using the setup shown in FIG. 3H, which includes the major components in FIG. 3G. The operation waveforms are presented in FIG. 3I, which shows the write and read phases of the LUT cell. After programming the FeFET into high-VT_{TH}/low-V_{TH} states using −4 V/+4 V, 1 μs write pulse, the output voltage shows a logic high and low, respectively. This verifies the successful cell operation, but due to the discrete experimental setup, performance is limited by the parasitics. In order to predict the fully-integrated FeFET LUT performance, SPICE simulations using a calibrated FeFET model and 45 nm Predictive Technology Model for logic transistor (PTM) are performed. Results indicate hat for a 6-input LUT cell, the read delay is 124.3 ps and consumes 13.1 μW power. In the subsequent section, FeFET based primitive components, including LUTs, CBs, and SBs, are also compared with other technology implementations using consistent SPICE simulations.

To support dynamic reconfiguration, two LUTs forming an array are designed and an additional multiplexer is used to select which configuration should be active in current operating period, as shown in FIG. 3J. Programming in a bulk planar single FeFET array has been extensively investigated. The applicable programming schemes depend on the number of accessible terminals during memory write. In the inventive FPGA architecture, the source/drain terminals are not simultaneously accessible from outside, which limits the possibility of applying write schemes that need to apply the source/drain voltages. In this case, a convenient solution is shown in FIG. 3J, where the gate and the body terminals are used for programming. The word line (WL) is shared among all FeFETs in a configuration block and the body is shared across different configuration blocks. Two step programming will then be performed where all the FeFETs in a configuration are set to the low-V_{TH} states first by applying a positive write voltage (i.e., V_{W}) on the WL and keep all the other terminals grounded. Then those FeFETs need to be in the high-V_{TH} states are applied with a negative gate-to-body voltage (i.e., −V_{W}). To avoid write disturb to those low-V_{TH} states FeFETs during the second step, the standard inhibition bias scheme (e.g., V_{W}/2) can be applied.

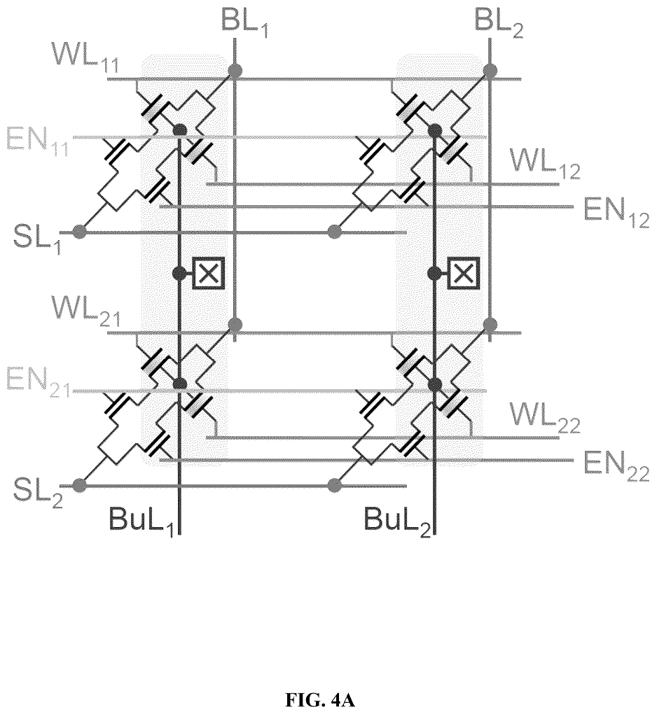

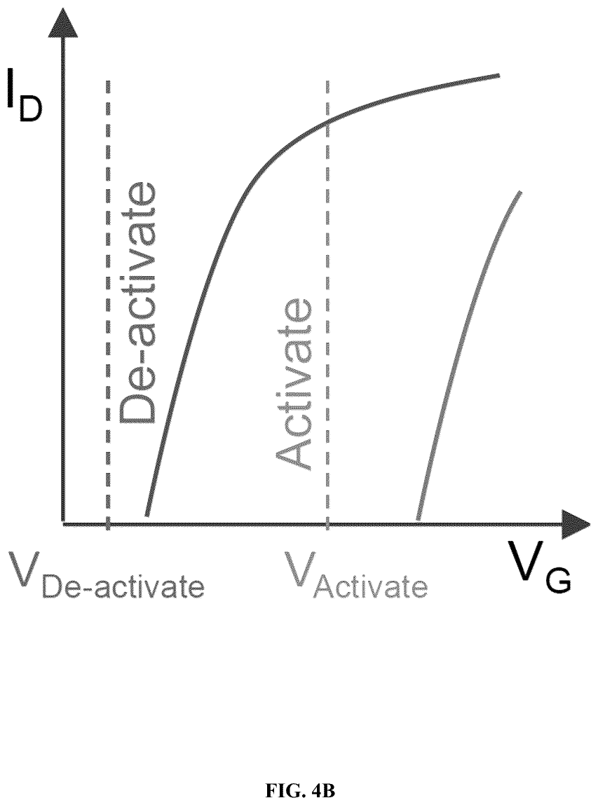

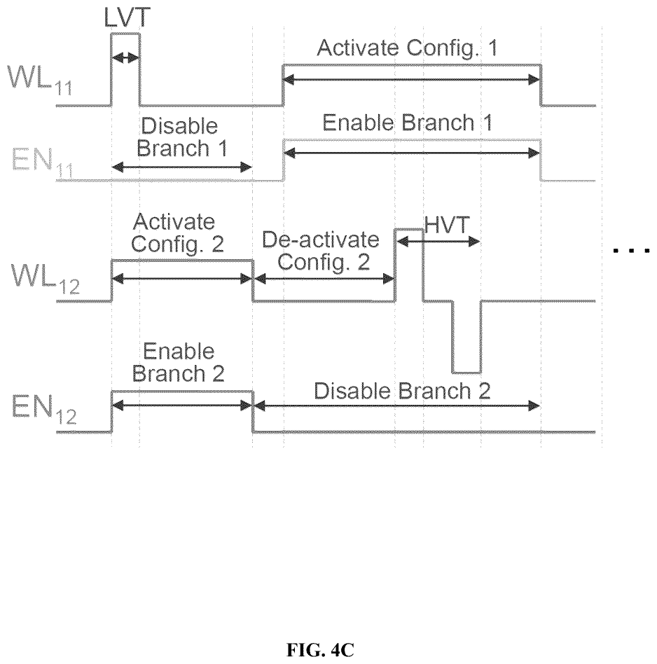

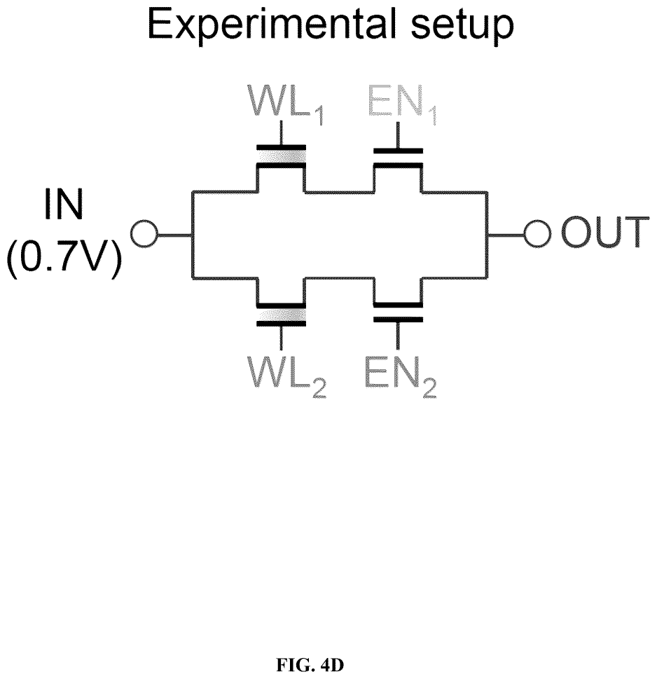

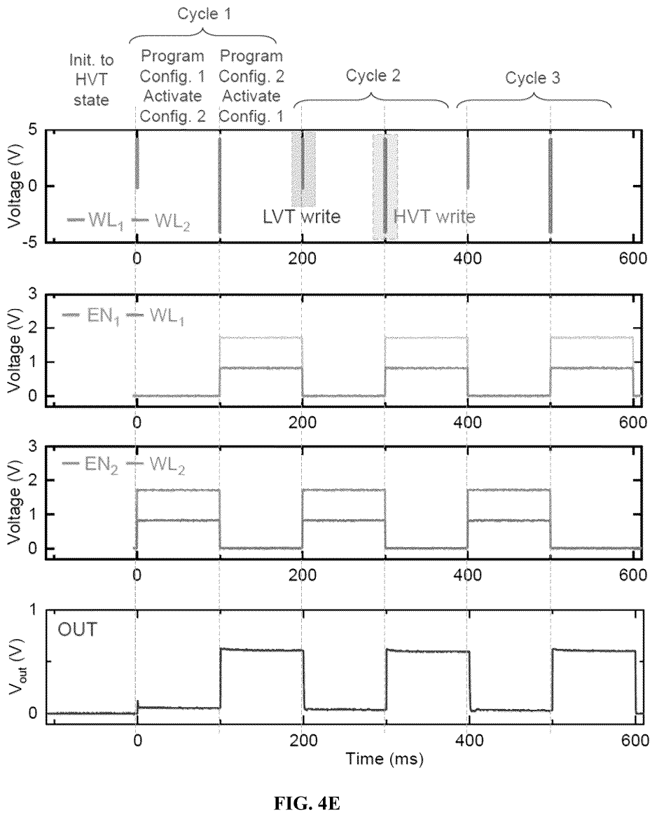

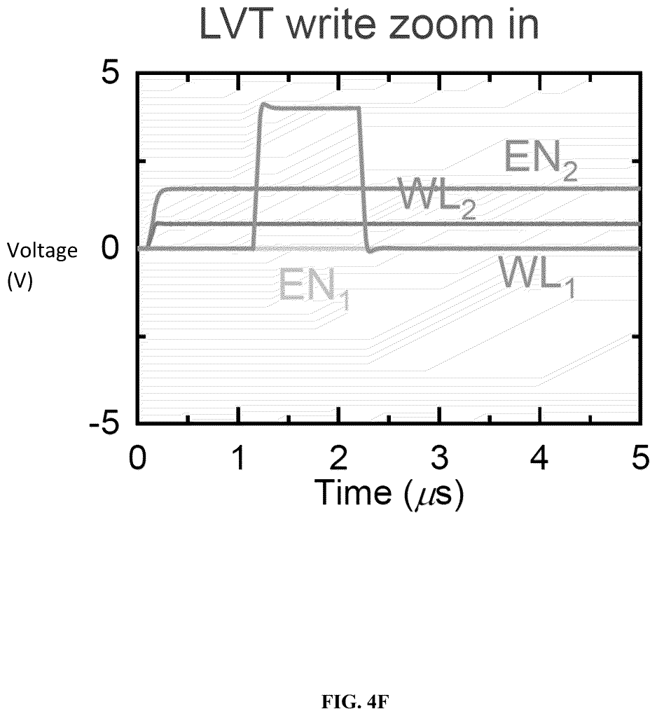

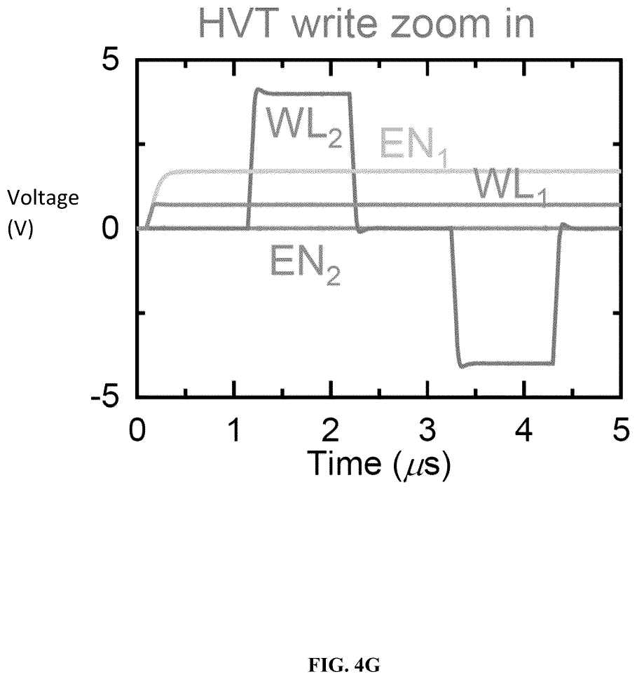

Next the functionality of the routing elements is verified, as shown in FIGS. 4A-4G. Using CB as an example, FIG. 4A shows the array structure, where bit line (BL) and source line (SL) route the actual signal, and WL and the column-wise body contact are used to program FeFETs. As introduced in FIG. 2C, to support the run-time reconfiguration of one branch without interrupting the normal operation of the other branch, a serial transistor is added to each branch and is off/on during configuration loading/execution, respectively. The swap between configurations can be easily and swiftly conducted by applying corresponding read gate biases, as shown in FIG. 4B, such that when one configuration is de-activated, the FeFET will be cut-off, irrespective of its states. FIG. 4C shows an example waveform applied on a testing unit (FIG. 4D), where the branch 1 is first configured to be the low-V_{TH} state while branch 2 is executed and then branch 1 is activated while the branch 2 is configured to the high-V_{TH} state using the two-step programming. FIG. 4E shows the experimental results applied the voltage sequence shown in FIG. 4C for three repeated cycles. The zoomed-in programming waveforms for branch 1 and branch 2 are shown in FIGS. 2F and 2G, respectively. Due to the configurations used in this testing scenario, where the branch 1/branch 2 is in the low-V_{TH}/high-V_{TH} states respectively, the output signal will therefore switch between 0.7 V (i.e., when branch 1 is active) and 0 V (i.e., when branch 2 is active). The experimental results therefore confirm successful operations. Experimental results of the other three configuration combinations of two branches further verifies the successful run-time reconfiguration operation. Similar to the LUT cell case, SPICE simulations are conducted to predict the speed of a fully integrated CB, where the simulated transient waveform of an exemplary multi-configuration CB is analyzed.

### Evaluation and Application Case Study

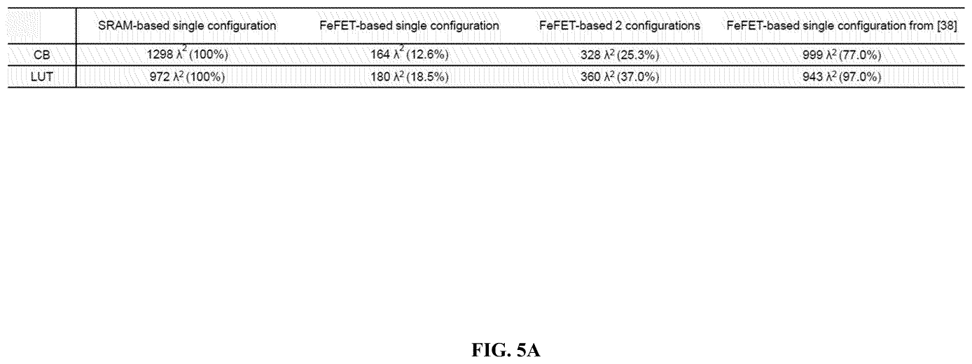

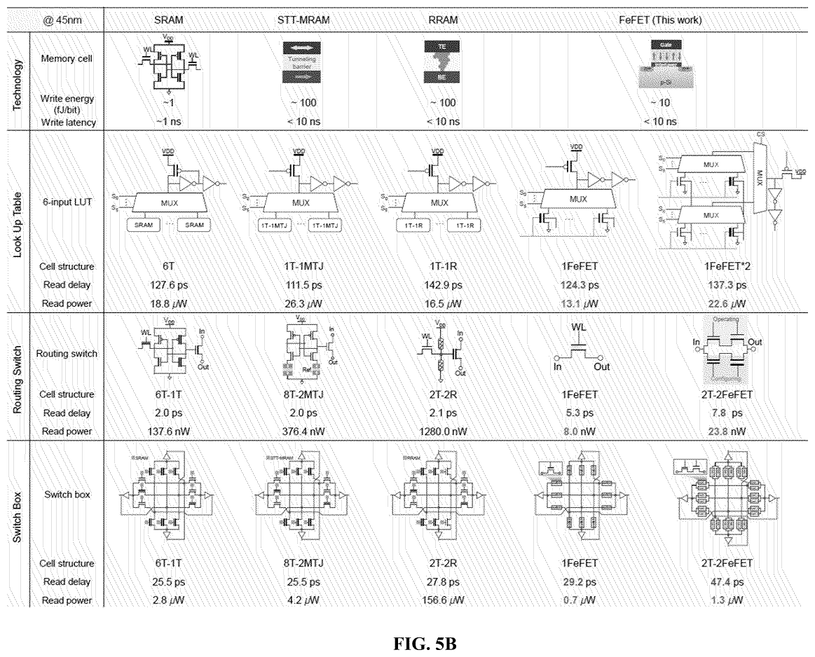

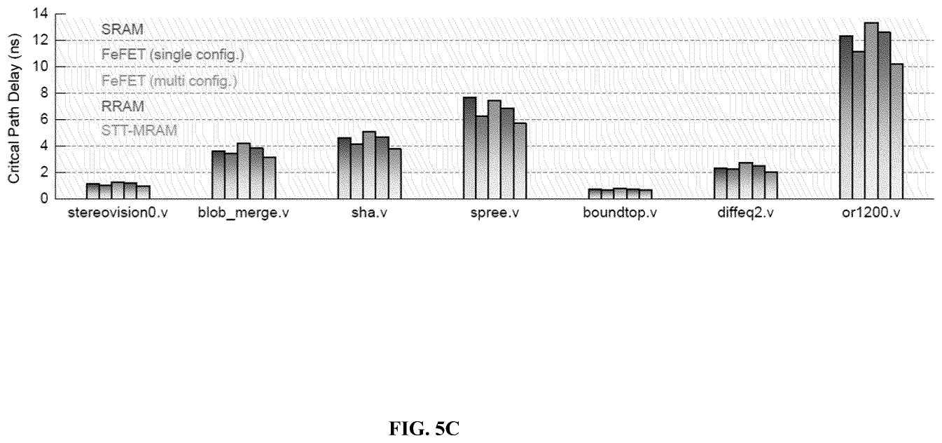

To evaluate the feasibility and performance of the inventive FeFET-based context-switching FPGA architecture, simulations are performed and a comprehensive comparison with other relevant works based on different memory technologies is shown in terms of area, delay and power consumption. Moreover, at the system level, the capability of the inventive architecture to successfully achieve dynamic reconfiguration is demonstrated and the evaluation results show that the design presents a significant power reduction and area efficiency improvement with slightly increased critical path delay as the trade-off. To estimate the area of FeFET-based CB and LUT cell and compare with other works, the layouts are drawn and the area is calculated using the design rules of GPDK 45 nm library. All relevant area numbers are shown in FIG. 5A. The layout analysis shows that the inventive CB and LUT cell are more compact compared to SRAM CBs and LUT cells. For example, the inventive FeFET-based single configuration CB and LUT cell, occupy area that is only 12.6% and 18.5% of their respective SRAM-based counterparts while the prior FeFET-based CB and LUT cell require 77.0% and 97.0% of that area, respectively. Even the inventive multi-configuration FeFET CB and LUT cell area is only 25.3% and 37.0% of that of the SRAM-based single configuration design. Therefore, the inventive design shows a significant area reduction compared to SRAM-based design and previous FeFET-based design.

FIG. 5B summarizes the basic structures of 6-input LUT/CB/SB based on existing memory technologies (SRAM, STT-MRAM, RRAM and FeFET), and compares their corresponding read delay and read power consumption. All circuits are simulated with HSPICE. The 45 nm Predictive Technology Model is adopted for all MOSFETs in this work and a calibrated FeFET model is used for the inventive design. For resistive memories, the corresponding low resistance and high resistance levels are used for simulation. According to the simulation results (FIG. 5B), for a 6-input LUT, the single configuration LUT shows the smallest read power consumption, which is 13.1 μW, and for multiple configurations, this number increases slightly but still less than the power consumed by MTJ-based single configuration LUT. This is due to the large on/off ratio of FeFET obviating the need for a high read current to differentiate its two states, unlike MTJ designs. As for the read delay, RRAM-based single configuration LUT has the longest latency. The inventive FeFET-based single configuration LUT shows the second best latency in all considered nonvolatile LUTs. Besides, the delay of the inventive FeFET-based multiconfiguration LUT is less than that of RRAM-based single configuration LUT even though considering one extra multiplexer for selecting configurations. The switching current through the sense amplifier for FeFET is larger than RRAM due to its higher on/off ratio (lower Rₒₙ), resulting in less LUT delay than RRAM. For CBs, the inventive 1Fe-FET single configuration CB and 2T-2FeFET multi-configuration CB show much less power consumption during operation, which consume ˜95%/˜85% less power than the SRAM-based CB. For SBs, both FeFET-based single configuration SB and multiconfiguration SB show much less power consumption than others since our circuit contains less transistors. However, the delay of 1FeFET CB is around 2× times of that of a SRAM-based CB. The delay of FeFET-based SB is worst among different memory technology based designs. That is because FeFET's transmission speed is not so high as a conventional MOSFET, resulting in poorer performance as CB. In conclusion, the inventive FeFET-based designs (CB/SB) show significant advantages on power consumption over SRAM/STT-MRAM/RRAM based designs but with the slight penalty in delay. Note that the penalty in the routing elements'(CB/SB) delay does not necessarily mean that the overall system will be impacted as the routing delay may be a small portion of the overall system delay, which is investigated below (FIG. 5C).

In order to investigate the impact of the primitive (i.e., LUT/SB/CB) delay on the latency of the whole FPGA, the critical path delay is studied with the verilog-to-routing (VTR) tool. The VTR tool is a popular open source CAD tool for FPGA architecture development and evaluation. For fair comparison, all the SRAM-/RRAM-/STT-MRAM-/FeFET-based FPGAs employ a well-optimized and commercial FPGA architecture using 45 nm technology in VTR. To get the critical path delay of different memory technology based FPGAs, 7 circuitry benchmarks (stereovision0, blob merger, sha, spree, boundtop, diffeq2, and or1200) included in VTR are conducted. These represent popular applications in diverse domains, such as image processing, math, cryptography and computer vision. FIG. 5C compares the critical path delay measured from SRAM-/RRAM-/STT-MRAM-/FeFET-based FPGAs. Compared with SRAM-based FPGA, the FeFET-based single configuration FPGA presents 8.6% reduction in the critical path delay on average, and it is also better than RRAM-based architecture. However, the inventive FeFET-based multi-configuration FPGA shows 9.6% increment in the critical path delay compared to SRAM-based FPGA. The simulation confirms that the delay of LUTs is dominant in the overall delay of the entire FPGA, therefore explaining the aforementioned performance of these FPGAs.

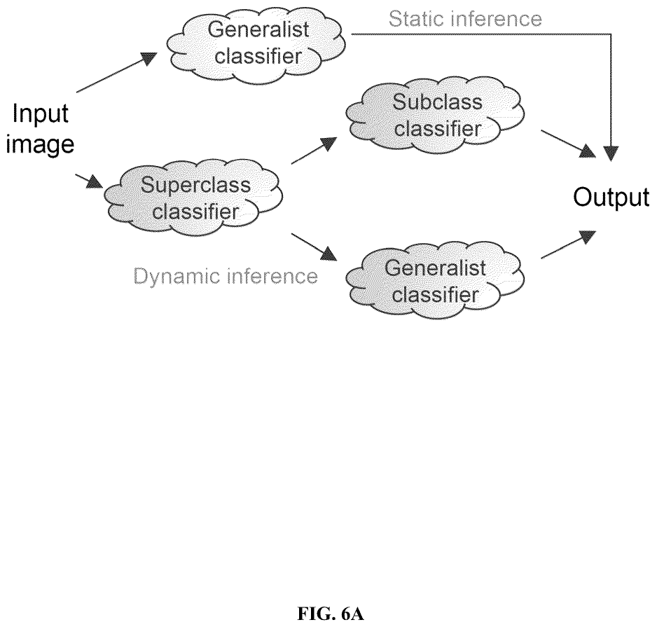

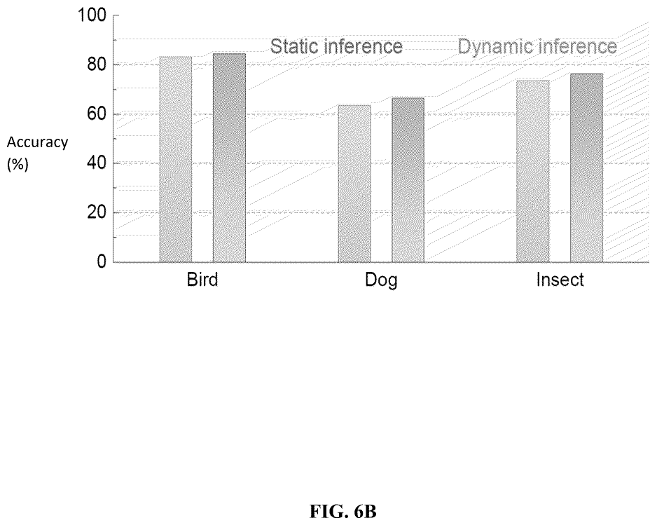

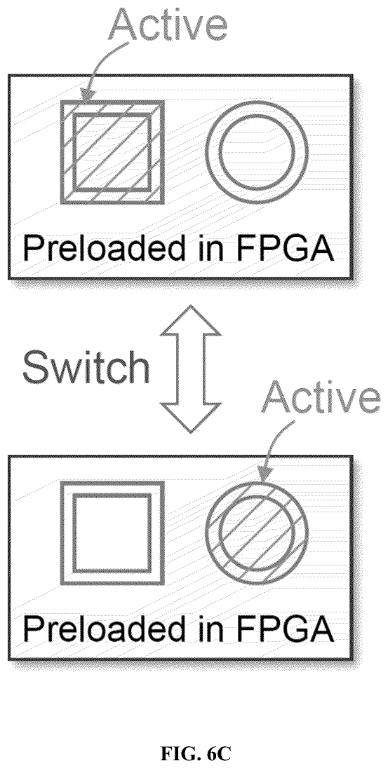

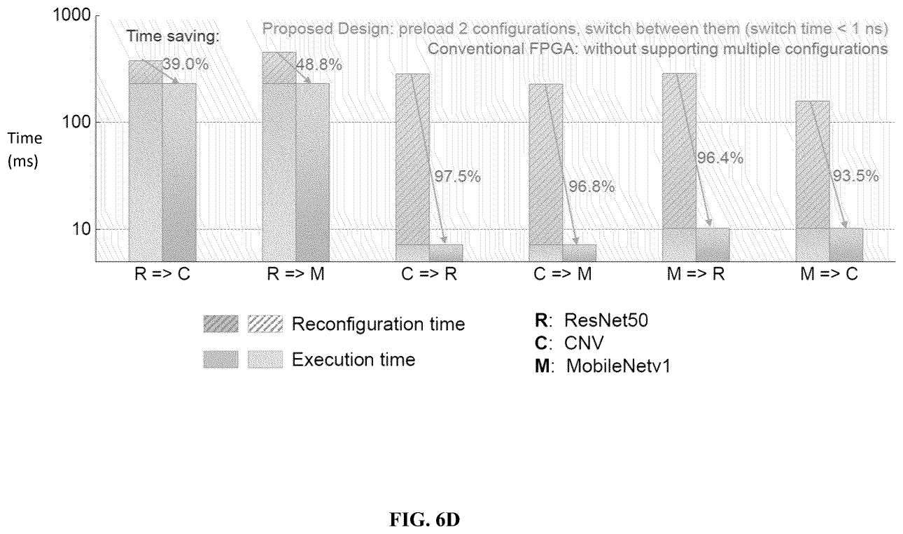

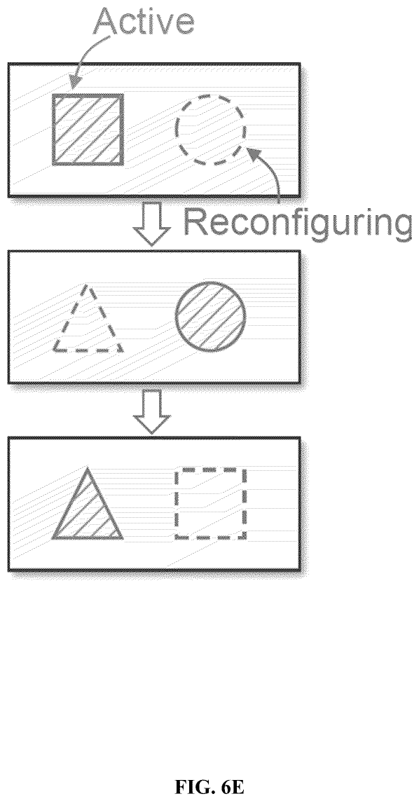

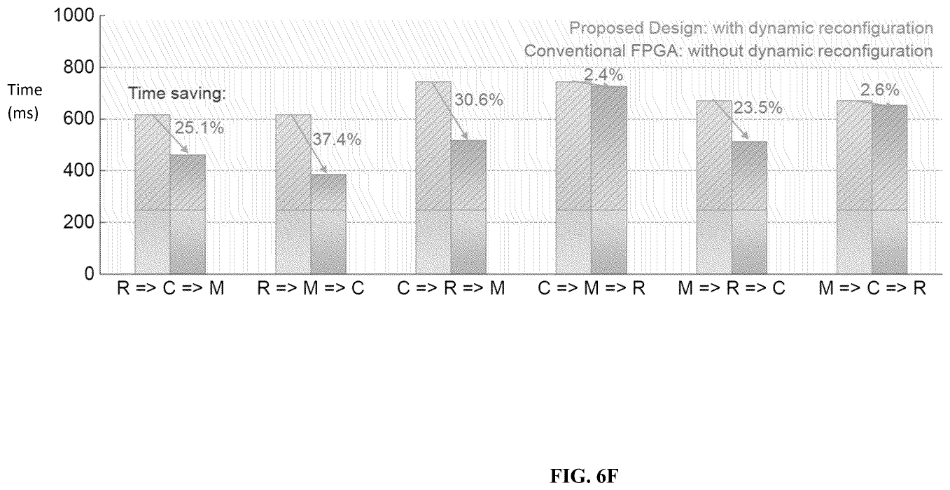

In addition, to show the feasibility of implementing the whole design in deep learning applications, three case studies under different scenarios are investigated. The first case is presented to show the benefit provided by dynamic reconfiguration in image classification. In the evaluation, two approaches of inference are considered - static inference and dynamic inference. For static inference, the input image is classified by the generalist classifier. However, for dynamic inference, the input image is first classified by the superclass classifier to identify the superclass. If the superclass is supported by the specialist subclass classifier network, then the configuration of the subclass classifier would be switched and executed for enhanced accuracy. Otherwise, a generalist classifier is invoked to complete the subclass identification. The whole workflow is shown in FIG. 6A. FIG. 6B shows that dynamic inference for super class classification improves the accuracy by up to 3.0% over static inference. Only context-switching FPGA can efficiently realize dynamic inference. In last two cases, the feasibility and advantages of the inventive design over the conventional FPGA design are evaluated in terms of timing when considering various application scenarios. Basically, three neural networks (ResNet50, CNV, and MobileNetv1) are deployed into FPGA through Xilinx Vitis AI platform. In the second case study, a case scenario that needs to switch between two neural networks frequently (FIG. 6C) is considered.

In conventional FPGA, it is necessary to load new configurations before switching contexts, which is time consuming. However, for this context-switching design, our approach can preload two configurations, and then freely switch between them without the reconfiguration latency. The switch time of the inventive design is less than 1 ns which is much smaller than reconfiguration time and the inventive design shows significant speed up (from 39.0% to 97.5% (FIG. 6D). The last case study is related to dynamic reconfiguration. It is assumed that there are three different neural networks to implement and switch between. Thus, in this case, there would be six situations corresponding to six combinations of these three networks (ResNet50→CNV→MobileNetv1, ResNet50→MobileNetv1→CNV, CNV→ResNet50→MobileNetv1, CNV→MobileNetv1→ResNet50, MobileNetv1→ResNet50→CNV, and MobileNetv1→CNV→ResNet50). As is well-known, latency is one of the most critical criteria when evaluating a neural network accelerator. Hence, for all these six situations, the total consumed time, including both the execution time and the reconfiguration time for each network, is compared under two different conditions - one is in conventional FPGA, the other is in the inventive architecture with dynamic reconfiguration.

As shown in FIG. 6E, as the capability of dynamic reconfiguration means that the architecture is able to operate and reconfigure simultaneously, some parts of or even the complete reconfiguration time of the following network can be overlapped and hidden by the execution time of current network, which helps to reduce the total latency. As shown in FIG. 6F, the results demonstrate that the inventive design with dynamic reconfiguration offers time saving for all these situations which varies from 2.4% to 37.4%. One thing should be noticed is that the maximum time saving of the ideal case would be 50%, in which the execution time of the first network is equal to the configuration time of the second network. The maximum improvement of the inventive design (37.4%) is very close to this number. Additionally, the inventive FPGA architecture is adaptive to implement more deep learning frameworks, and the relevant improvements and benefits are investigated. Above all, the case studies demonstrate that the inventive FeFET-based context-switching FPGA design shows the best adaptability in various types of deep learning applications.

In summary, embodiments of the disclosed FeFET-based context-switching FPGA architecture provides the capability of dynamic reconfiguration, which can mitigate the tradeoff in conventional FPGA between the chip area cost and reconfiguration latency. In addition, test results experimentally verify the functionality of the primitive blocks of the inventive FPGA. The simulation results reveal that by leveraging FeFETs, the inventive primitives of the FPGA show huge area and power reduction compared to conventional SRAM-based design. Moreover, three representative application scenarios are investigated and studied. The evaluation results show the invenitve context-switching FPGA supporting dynamic reconfiguration offers significant time saving in these application scenarios. The inventive design provides an efficient solution to bridge the gap and makes FPGA more competitive in accelerating complex deep learning applications.

### Materials and Methods

### Device Fabrication

The fabricated ferroelectric field effect transistor (FeFET) features a polycrystalline Si/TiN/doped HfO2/SiO2/p-Si gate stack. The devices were fabricated using a 28 nm node gate-first high-κ metal gate CMOS process on 300 mm silicon wafers. The ferroelectric gate stack process module starts with removing the native oxide through wet etch, then the growth of a thin SiO₂ based interfacial layer through wet chemical oxidation, followed by the deposition of the doped HfO2 film through atomic layer deposition (ALD). A TiN metal gate electrode was deposited using physical vapor deposition (PVD), on top of which the poly-Si gate electrode is deposited. The source and drain n+ regions were activated by a rapid thermal annealing (RTA) at approximately 1000° C. The reason that a 1000° C. is used is because the source/drain dopant activation and the ferroelectric phase stabilization are performed at the same step. This is the gate-first process. Of course, lower temperature can be used if gate last process is adopted. With Hf1-xZrxO2, annealing at the back-end-of-line compatible temperature is even possible (≤450°C.). This step also results in the formation of the ferroelectric orthorhombic phase within the doped HfO2. After RTA, the HfO2 becomes poly-crystalline, where multiple crystalline phases can co-exist, including the monoclinic dielectric phase, orthorhombic ferroelectric phase, and tetragonal anti-ferroelectric phase. For future suppression of device variation, further optimization for phase-pure orthorhombic HfO2 is necessary. For all the devices electrically characterized, they all have the same gate length and width dimensions of 0.5 μm×0.5 μm, respectively.

### Electrical Characterization

The experimental verification was performed with a Keithley 4200-SCS Semiconductor Characterization System (Keithley system), a Tektronix TDS 2012B Two Channel Digital Storage Oscilloscope (oscilloscope), and a Keysight 81150A Pulse Function Arbitrary Generator (waveform generator). Two 4225-PMUs (pulse measurement units) were utilized to generate proper waveforms. The FeFETs used in experimental verification were connected with devices (inverters, p-type MOSFET, and/or n-type MOSFET) externally on a breadboard. In the experimental verification of the LUT cell operation, VDD was given by the waveform generator. Output pulses were captured by the oscilloscope. Write and read operations were provided by the Keithley system. In the experimental verification of the multi-configuration CB operation, input voltage was given by the waveform generator. Output pulses were captured by the oscilloscope. WL and EN signals were generated by the Keithley system. Three repeated cycles were performed for each configuration. State initialization (+4V or −4V to both WL1 and WL2 with pulse width 1 μs) was added at the beginning of the waveforms in order to generate a desired output in the first cycle.

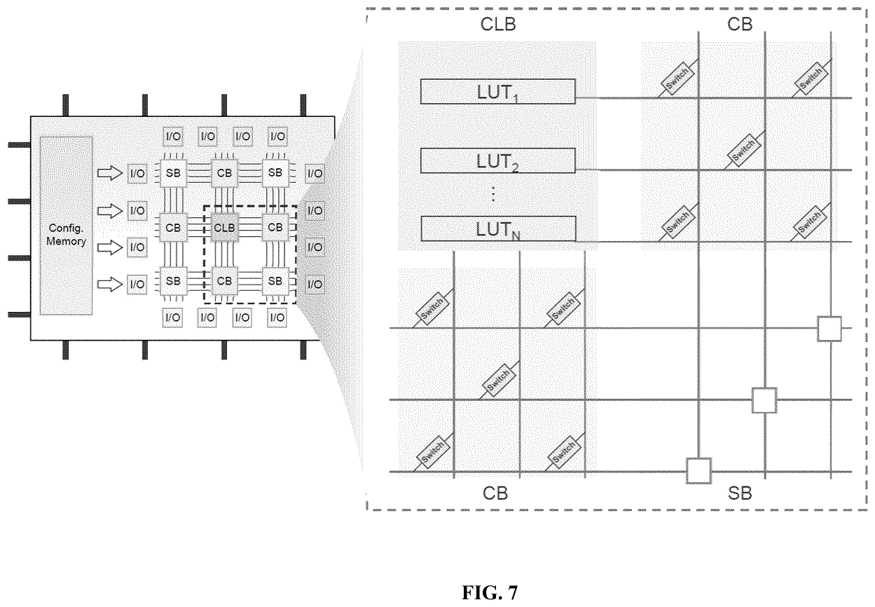

Referring to FIG. 7, a FPGA is an efficient and pre-fabricated silicon devices that can be programmed to implement all different functions of digital circuits by users. Although modern FPGA can be customized with different IP cores for specific functionalities, the backbone of FPGA for reconfigurability is composed of a sea of Configurable Logic Blocks (CLBs), Connection Blocks (CBs), Switch Blocks (SBs), configuration memory, and Input/Output (I/O) blocks. The configuration memory stores a huge amount of configuration bits which will be fed to control the functions of CLBs, the routing networks, etc. After configuration, FPGA can work efficiently as what users demand. Each CLB includes a bunch of LUTs. LUTs work as its name indicates—look-up tables, in which the stored contents (i.e., configuration bits) are selected by MUXs and outputs the correct results upon different select signals. Through LUTs, CLBs can realize all the logic functions, and further process all digital operations. As for routing components (CBs and SBs), the main element to construct them is the routing switch. A basic routing switch usually consists of a pass transistor and a memory cell storing configuration bits. Depending on bit ‘1’ or bit ‘0’ stored in the memory cell, the routing switch can be turned on or turned off so that passing or cutting off signals. In this way, CBs and SBs are able to build up the whole routing network. Reconfigurability is one of the biggest advantages of FPGAs. The speed of reconfiguration depends on how quickly the configuration bits can be loaded from the configuration memory. The extra overheads caused by the use of external configuration memory is a key challenge incurring high energy cost and long reconfiguration latency. Therefore, finding an efficient solution to reduce the loading of configuration bits from the memory is critical and eagerly.

### Retention and Endurance

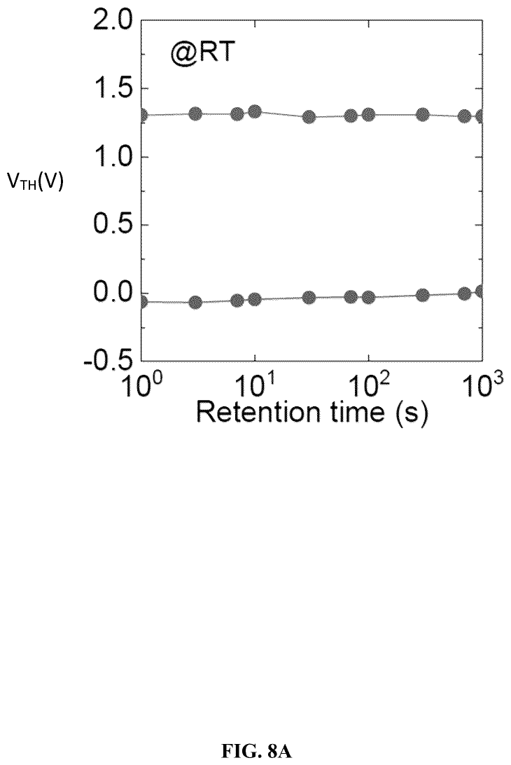

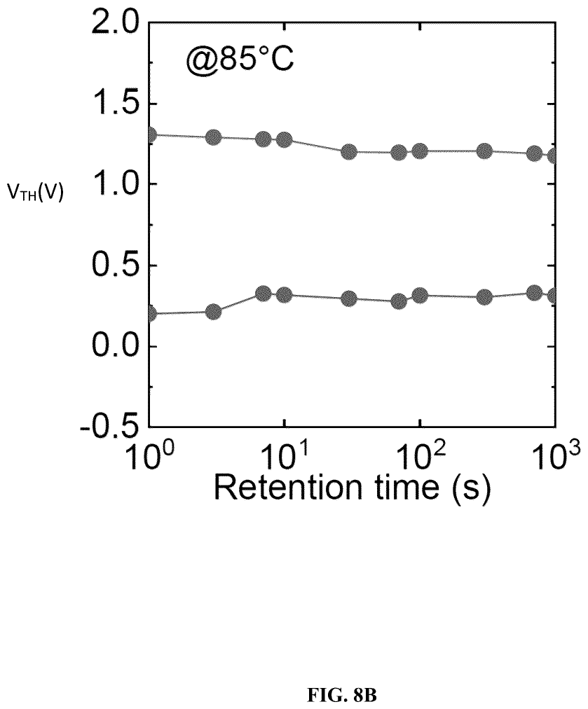

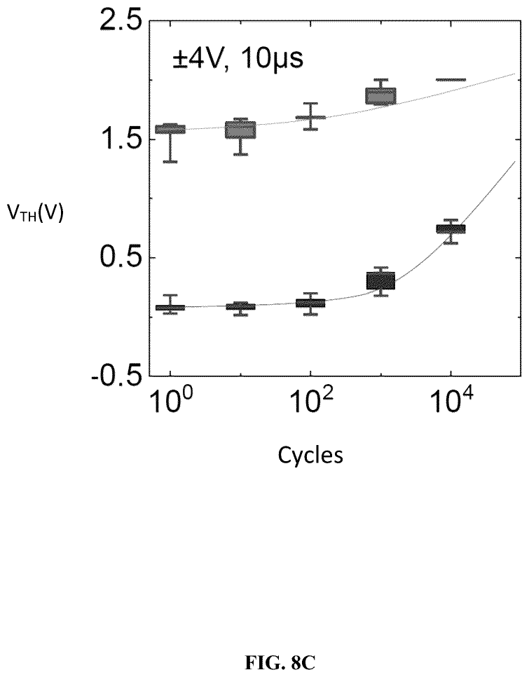

The testing devices are industrial device. Measurement data is illustrated in FIGS. 8A-8C. HfO2 based FeFETs generally show good retention, where almost no degradation is observed even at 85° C. The endurance of Si FeFET still remains a challenge, with one example shown in FIG. 8C, where endurance is around 10⁵ cycles. There are some work recently showing promising improvement up to 10⁸˜10¹⁰ cycles (55, 56). Since this remains an active research, much better endurance should be expected in the future. From the FPGA side, for some scenarios requiring frequent context switching and dynamic reconfiguration (e.g., changing AI models), it would not require more than 100 times per hour. And even with 100 times per hour, the inventive FeFET-based FPGA can support more than 114 years. For most of the normal scenarios, the reconfiguration of FPGA may be happening once a week or once a month. In these scenarios, the inventive FPGA would have a much longer lifetime. Even though in these scenarios where the frequency of reconfiguration is low, it will be important to react to a new condition and reconfigure rapidly. The inventive design can hide the reconfiguration latency completely by dynamic reconfiguration.

### Potential Applications

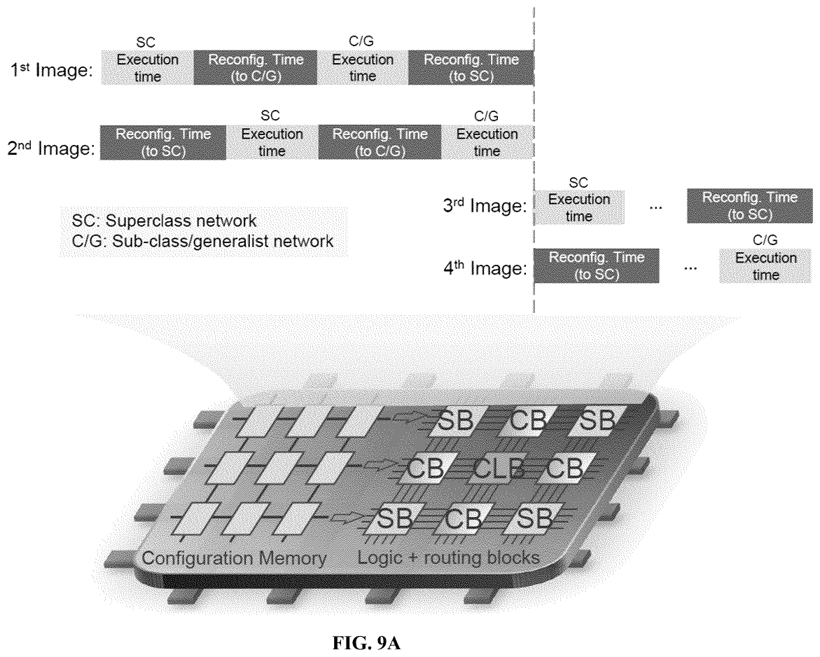

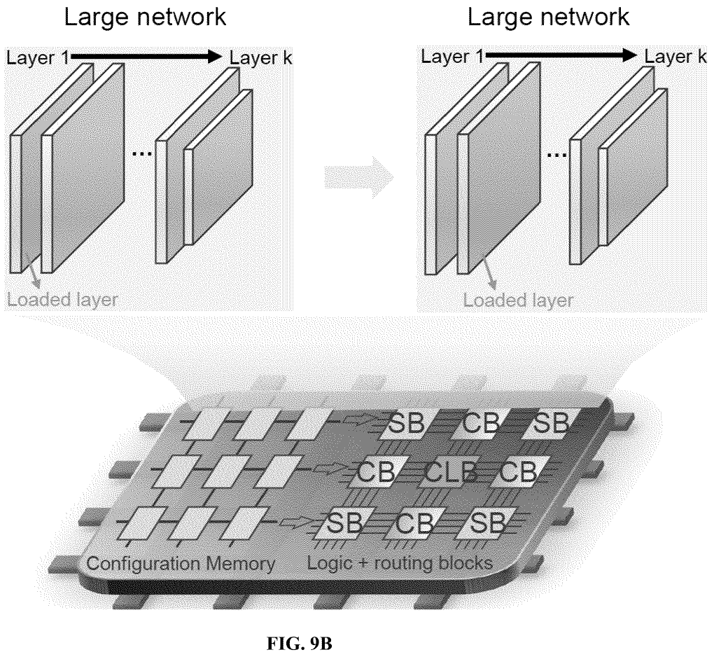

FIGS. 9A and 9B shows two potential applications of the inventive FeFET-based context-switching FPGA architecture. FIG. 9A shows the inventive design being used in image classification and to help reduce processing time dramatically for processing a large number of images. FIG. 9B shows that for some large and complex neural networks which cannot completely fit in general FPGA, the inventive FeFET-based context-switching FPGA architecture provides reliable solutions through dynamic reconfiguration.

In addition to the Super-Sub network application mentioned before, there are still a large number of deep learning applications which the inventive FeFET-based context-switching FPGA architecture can be suitable for or provide reliable solutions. Or the two potential application situations that are presented, one is a derivative situation of the Super-Sub network application. When there are a large number of images needed to be classified, conventional FPGA without dynamic reconfiguration would inevitably require an extremely long time to process all these images due to the serial process mechanism. However, for the context-switching FPGA enabling dynamic reconfiguration, the processing time can be reduced dramatically since the inventive design supports multiple configurations and enables the capability of reconfiguring and executing simultaneously. More specifically, the inventive design only requires eight cycles to finish the task of image classification of four images while conventional FPGA would require more than sixteen cycles in the same situation.

The other potential application situation is for those large and complex neural net-work implementation. In recent years, with the increasing demand of massive data and complex computation, network models are becoming more and more complex and contain more layers, which makes it much more difficult to implement them in hardware. Aiming at alleviating this issue, the inventive FPGA architecture provides reliable solutions through dynamic reconfiguration. Basically, part of the target network can be implemented in firstly, and then the rest of layers can be loaded without interruption by dynamic reconfiguration. In this way, those large network models can be successfully fit in a normal-size FPGA.

### Simulation Details of LUT

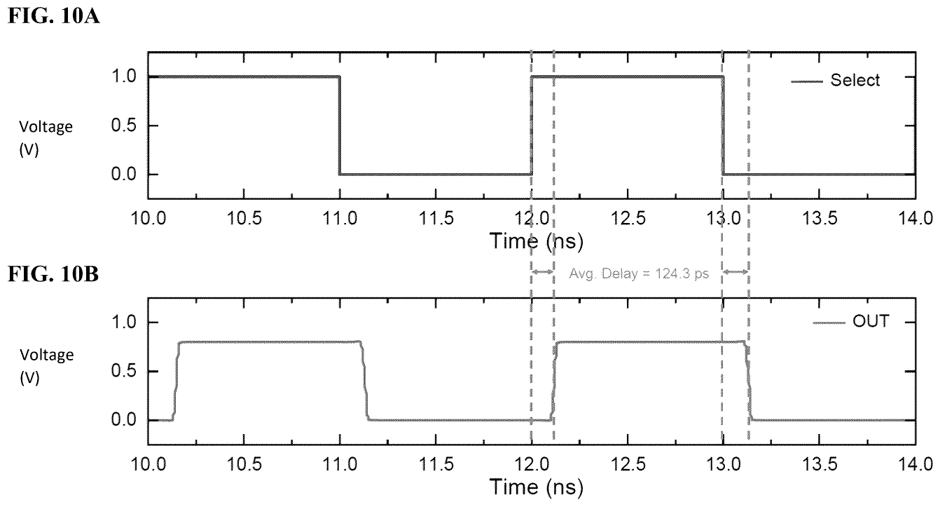

FIGS. 10A and 10B illustrate the simulation waveform of the select signal and the output signal during read stage in the 6-input FeFET LUT, respectively. All the simulations are done in HSPICE. A pulse signal (1V) is given to control the multiplexer and select LUT cells. During the read stage, different LUT cells would be selected and the configuration bits stored in would be passed to Output. According to the waveform and measurement, the average read delay is around 124.3 ps.

### Two-Step Programming and Write Disturb of FeFETs

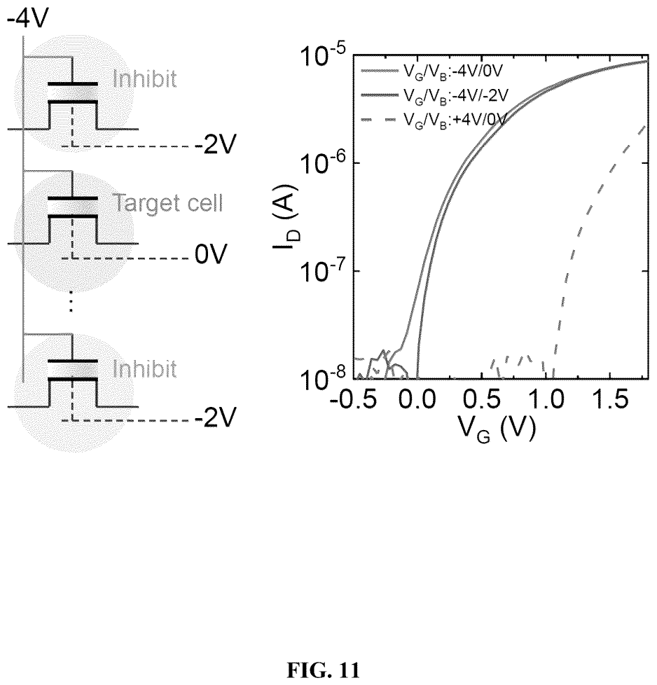

FIG. 11 illustrates the bias conditions for one configuration in the FeFET LUT during the second step of the two-step programming. After the first step, all the FeFETs have been programmed to the low-VTH state. Then depending on the stored information, those FeFETs need to be at the high-VTH state will be applied an −4 V across the gate and the body. For those FeFETs that need to stay at the low-VTH state, inhibition biases are applied to the body such that the gate-to-body voltage drop is only −2V, not enough to disturb state. Such a scheme has been successfully verified in the experiment.

### Multi-Configuration CB Validation

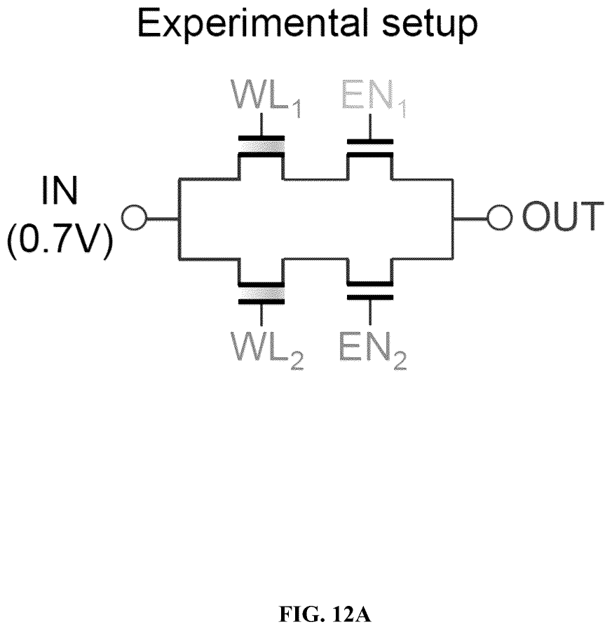

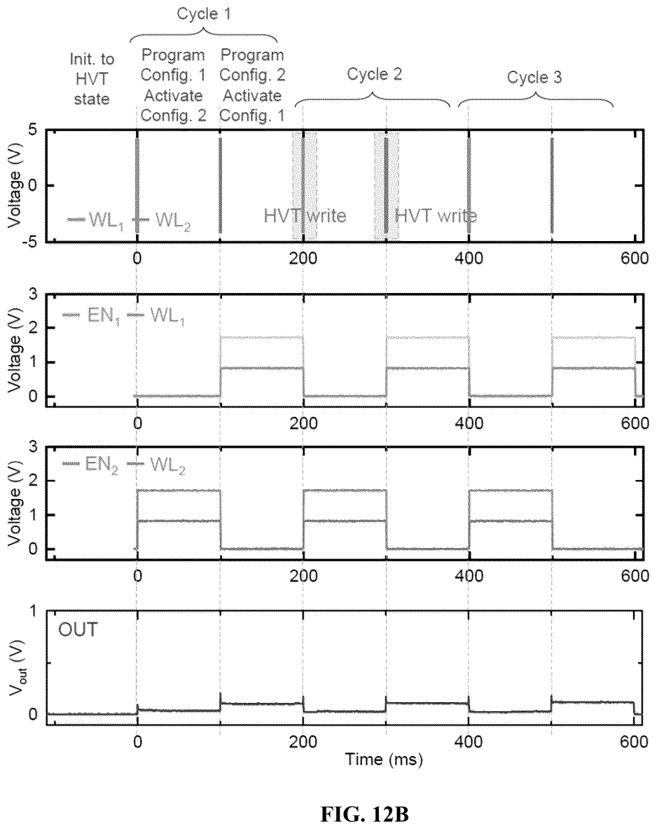

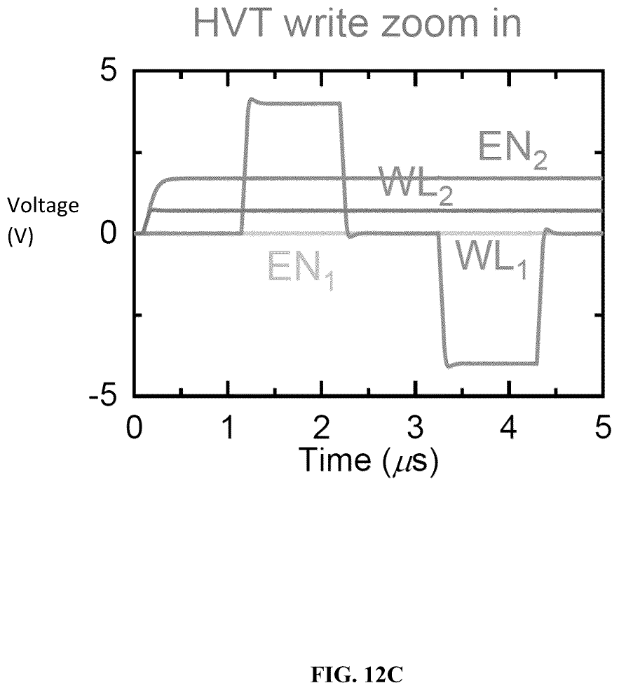

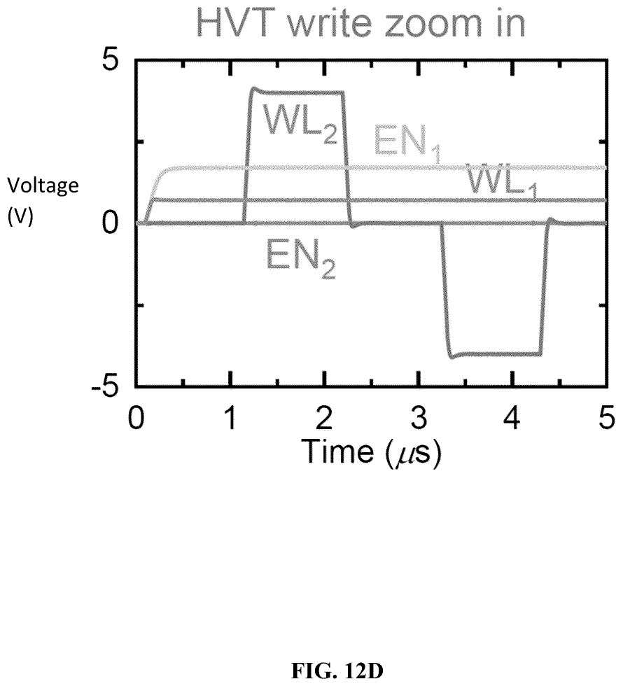

FIGS. 12A-12D show experimental verification of the multi-configuration CB operation when both branches are in the high-VTH states. FIG. 12A shows the circuitry of one CB test unit. FIG. 12B shows the experimental transient waveforms of run-time context configuration and switching repeated for 3 cycles. FIGS. 12C and 12D show the zoomed-in programming waveform for branch 1/branch 2 to the high-V_{TH} state, respectively.

In addition to the one combination in which the branch 1/branch 2 is in the low-VTH/high-VTH states respectively, the other three combinations are also verified experimentally.

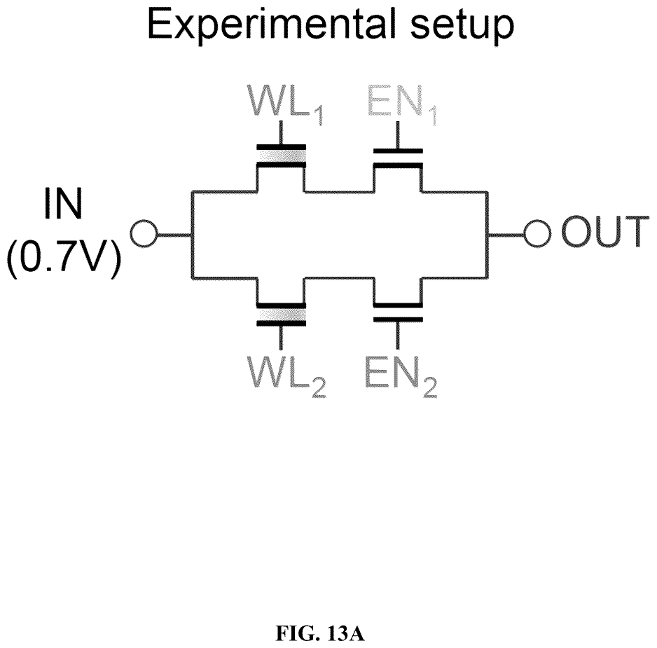

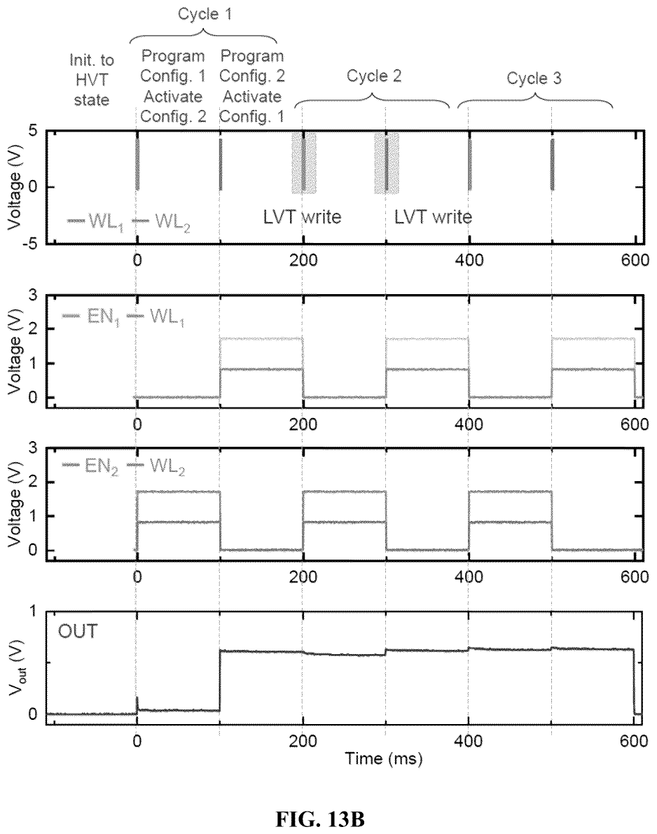

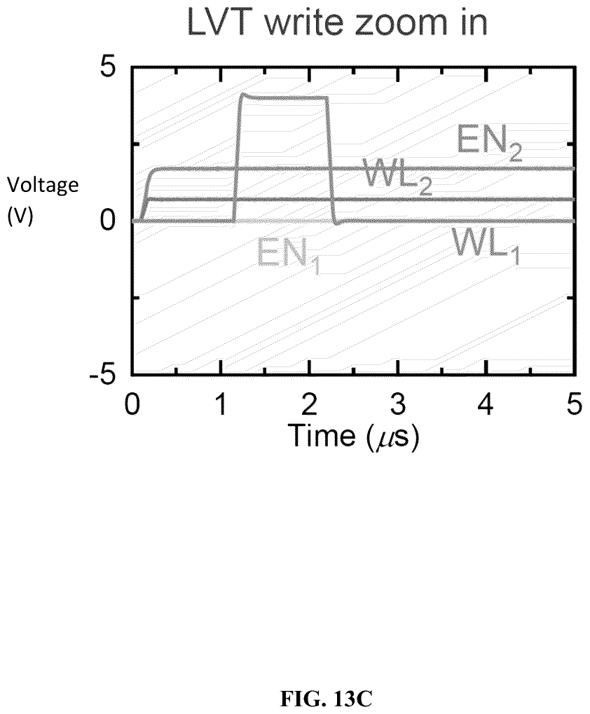

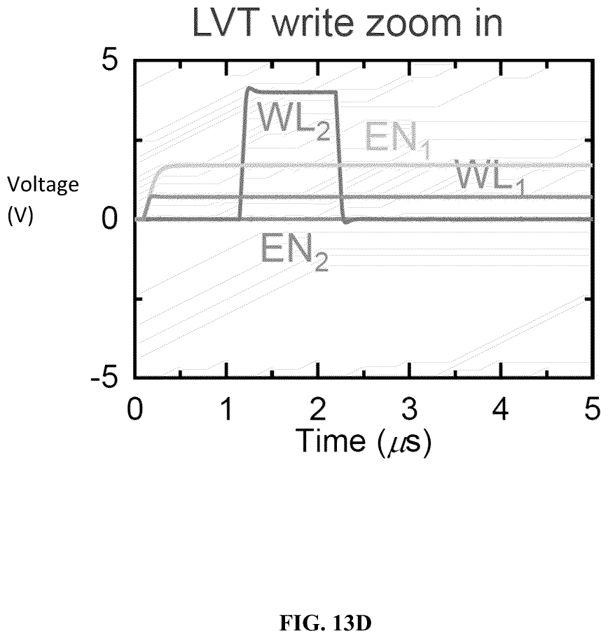

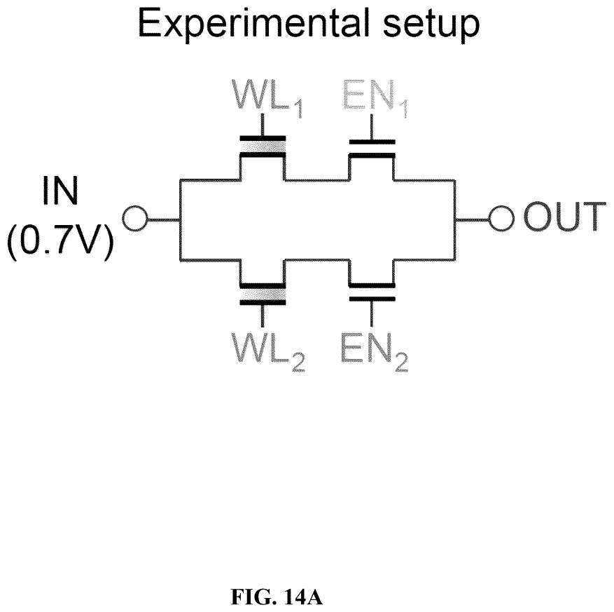

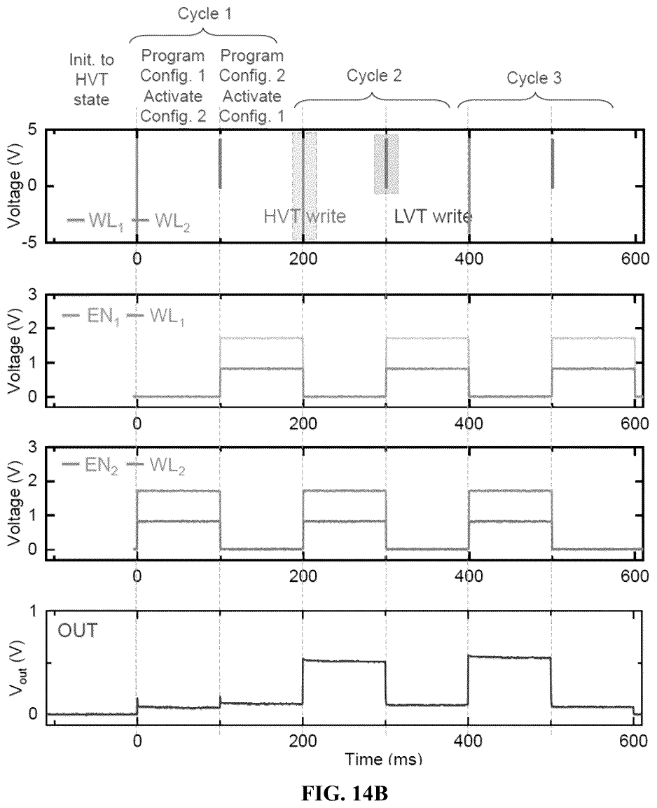

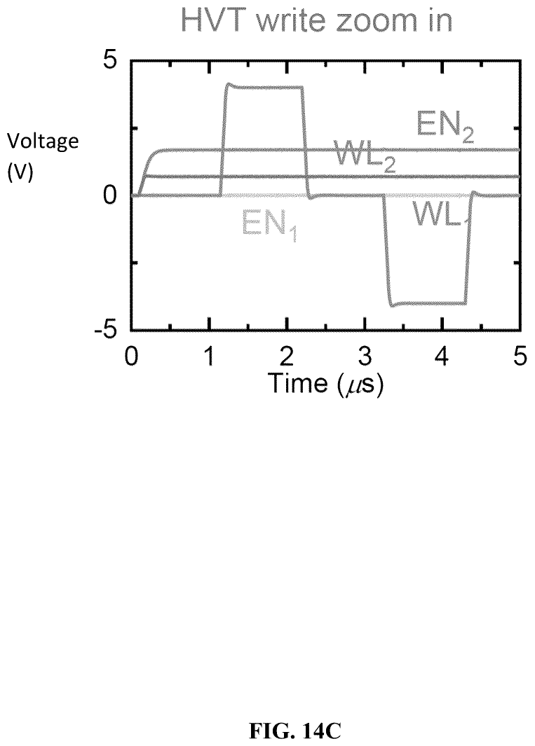

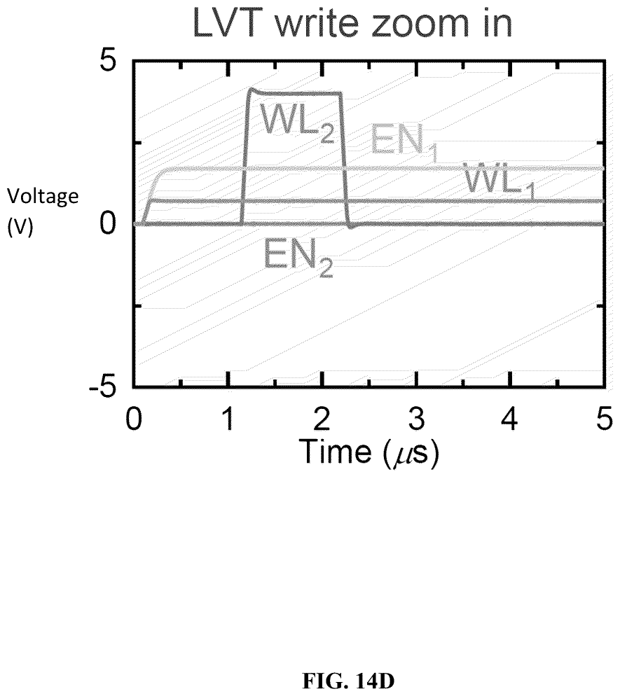

FIGS. 12A-12D show the results when the branch 1/branch 2 are both in the high-VTH states. In this case, no signal propagation happens, so the output remains low. FIGS. 13A-13D show the verification when the branch 1/branch 2 are both in the low-V TH states. In this case, except after the initialization, the output should remain high due to the signal transmission, as also shown in the experimental results. FIGS. 14A-14D show the verification when the branch 1/branch 2 are in the high-V_{TH}/low-V_{TH} states, respectively. In this case, the output will switch between high and low and it is high when the branch 2 is active. The first cycle is an exception because both branches are initialized to the high-V_{TH} states to begin with.

### Simulation Details of Multi-Configuration CB

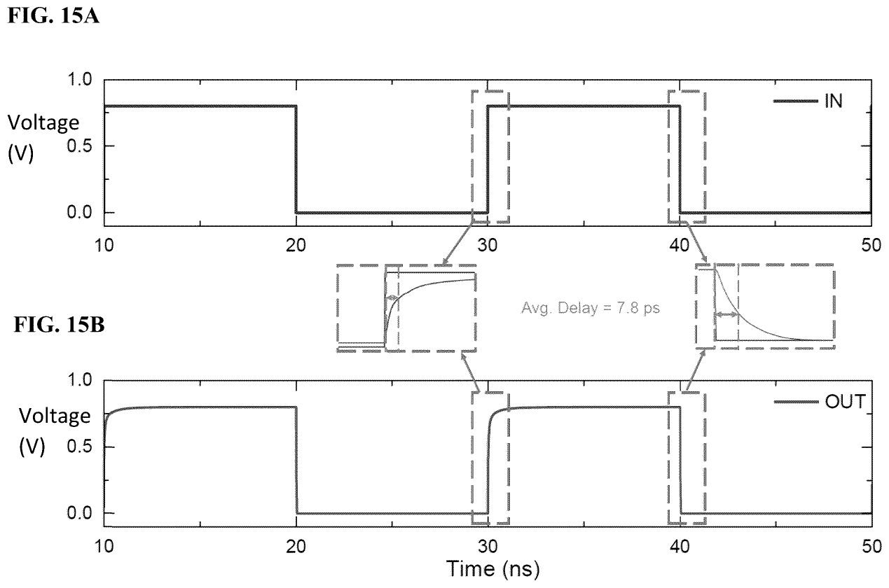

FIGS. 15A-15B illustrate the simulation waveform of the input signal and the output signal in the multi-configuration FeFET CB, respectively. All the simulations are done in HSPICE. In the simulation, a pulse input signal (0.8 V) is asserted to pass through the FeFET CB (FIG. 15A). On the output terminal, the same pulse would be detected with the delay (FIG. 15B), which is around 7.8 ps on average.

### Layout

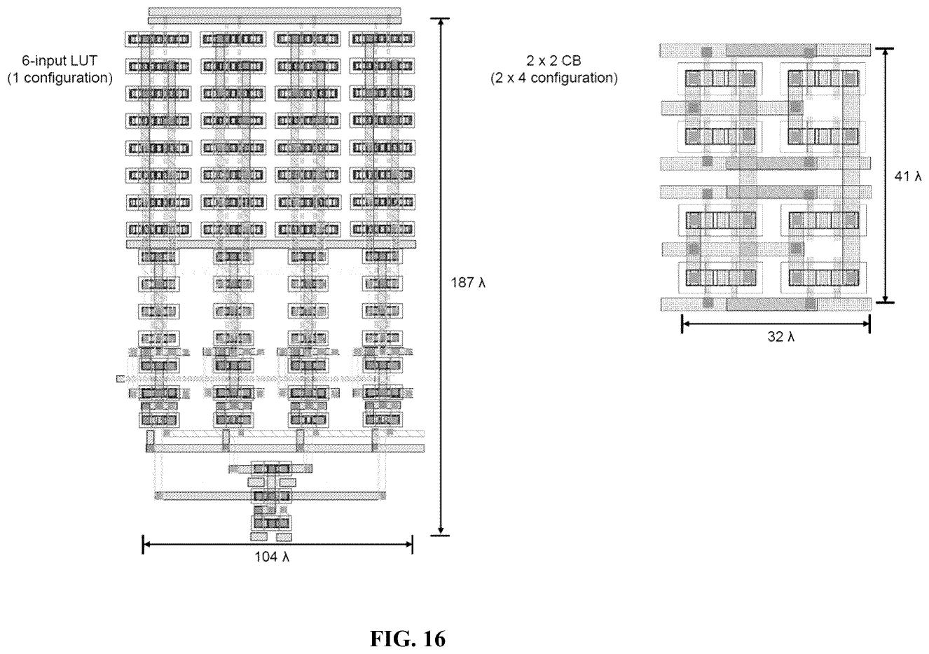

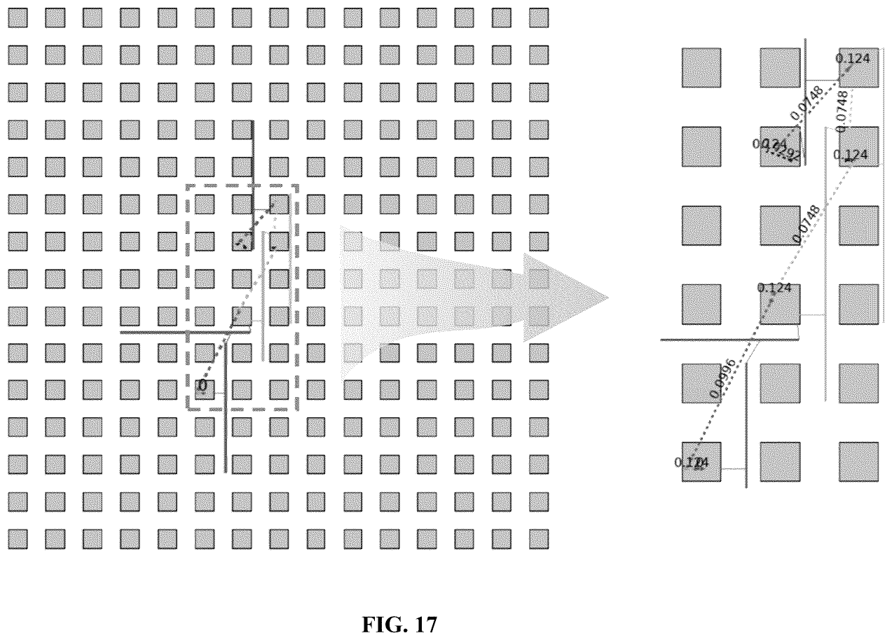

FIG. 16 (left panel) shows the layout of an inventive 6-input LUT. The LUT is 104 λ in width and 187 λ in length, so the total area is 19448 λ2 . The right panel in FIG. 16 shows the layout of an inventive 2×2 CB supporting dynamic reconfiguration which is 32 λ in width and 41 λ in length, so the overall area is 1312 λ2 . Note that all the layouts follow the design rules of GPDK 45 nm library.

### Critical Path Delay

VTR was used to get the critical path delay of the inventive FPGA architecture when implementing different benchmarks. FIG. 17 shows an example with stereovision0 benchmark captured from VTR. The left panel shows the overall FPGA architecture, and the right panel shows the details on its critical path with corresponding delay numbers after implementing stereovision0 benchmark.

### Case Study

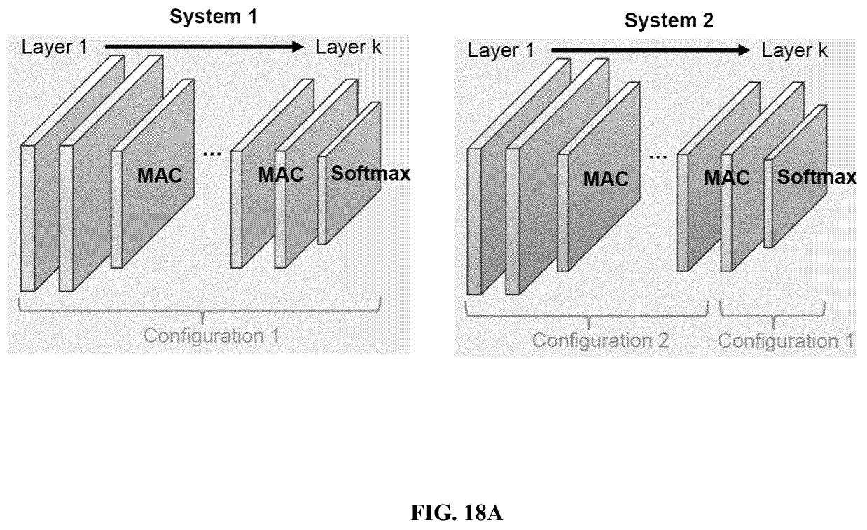

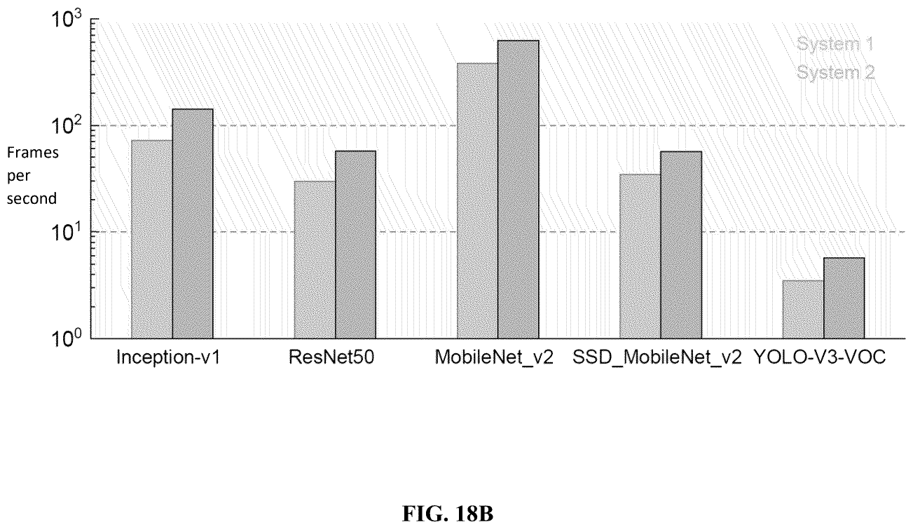

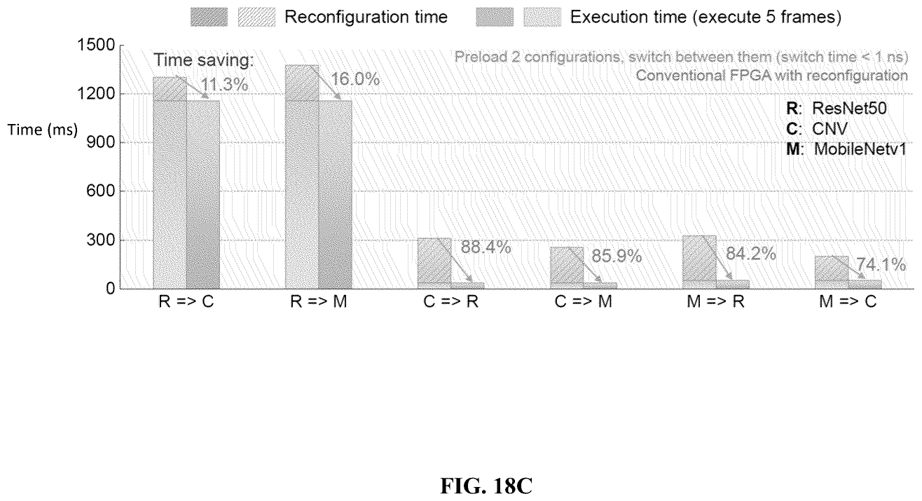

In this section, cases are introduced for implementing the inventive FPGA design into deep learning applications and show the benefits of our design. The first case relates to dynamic configuration switching in DNN to show the performance improvement provided by dynamic reconfiguration in deep learning applications. Basically, there are two systems used in the case. As illustrated in FIG. 18A, in System 1, a Xilinx DPU B1152 core with softmax for accelerating an entire neural network is delpoyed. However, as a comparison, System 2 consists of a Xilinx DPU B2304 core without softmax for accelerating all but the last layer of a neural network, and a Xilinx DPU B1152 core with softmax for accelerating the last layer of the neural network and softmax layer. The simulation results show that System 2 which employs dynamic switching of layer resources yields more throughput (˜1.7x) in DNN applications (FIG. 18B).

The other case is shown in FIG. 18C. In this case, the impact of dynamic reconfiguration on performance of FPGA in deep neural network domains is investigated. Hence, 3 neural networks (ResNet50, CNV, and MobileNetv1) into Xilinx AIveo U250 card via Xilinx Vitis AI (52) are implemented. To get the reconfiguration time of each network, the formula that the size of the bitstream over the port throughput is used to calculate the reconfiguration time. It is assume that the maximum bandwidth is performed with the reconfiguration ports (ICAP) which is 3.2 Gb/s. In addition, these built network models are ran in Vitis AI to obtain the estimated latency reports which are the execution time of different networks in U250 board. In some applications performing multiple networks, some of the networks should be patched before switching to another. The reason is that the former networks need to learn from these frames such that we can build a better network for current condition. In this situation, the feature of run-time reconfiguration of the inventive design is able to serve these kinds of applications perfectly. FIG. 18C shows another time saving under the condition that executes the first network 5 times, then switch to the second one. The total time saving decreases a bit as it is expected, but still remains around 88.42% at maximum. In conclusion, the inventive architecture which offers the capability of dynamic reconfiguration provides significant benefit on latency for various deep learning applications.

### REFERENCES

The following references are incorporated herein by reference in their entireties.
1. K. He, X. Zhang, S. Ren, J. Sun, Proceedings of the IEEE conference on computer vision and pattern recognition (2016), pp. 770-778.
2. G. Huang, Z. Liu, L. Van Der Maaten, K. Q. Weinberger, Proceedings of the IEEE conference on computer vision and pattern recognition (2017), pp. 4700-4708.
3. S. Ren, K. He, R. Girshick, J. Sun, Faster r-cnn: Towards real-time object detection with region proposal networks. Advances in neural information processing systems 28 (2015).
4. J. Redmon, S. Divvala, R. Girshick, A. Farhadi, Proceedings of the IEEE conference on computer vision and pattern recognition (2016), pp. 779-788.
5. J. Devlin, M.-W. Chang, K. Lee, K. Toutanova, Bert: Pre-training of deep bidirectional transformers for language understanding. arXiv preprint arXiv: 1810.04805 (2018).
6. Y. Liu, M. Ott, N. Goyal, J. Du, M. Joshi, D. Chen, O. Levy, M. Lewis, L. Zettlemoyer, V. Stoyanov, Roberta: A robustly optimized bert pretraining approach. arXiv preprint arXiv: 1907.11692 (2019).
7. A. Mehonic, A. J. Kenyon, Brain-inspired computing needs a master plan. Nature 604, 255-260 (2022).
8. J.-W. Chang, K.-W. Kang, S.-J. Kang, An energy-efficient fpga-based deconvolutional neural networks accelerator for single image super-resolution. IEEE Transactions on Circuits and Systems for Video Technology 30, 281-295 (2020).
9. J. Li, K.-F. Un, W.-H. Yu, P.-I. Mak, R. P. Martins, An fpga-based energy-efficient reconfigurable convolutional neural network accelerator for object recognition applications. IEEE Transactions on Circuits and Systems II: Express Briefs 68, 3143-3147 (2021).
10. K. Guo, S. Zeng, J. Yu, Y. Wang, H. Yang, [dl] a survey of fpga-based neural network inference accelerators. ACM Trans. Reconfigurable Technol. Syst. 12(2019 ).
11. S. D. Brown, R. J. Francis, J. Rose, Z. G. Vranesic, Field-programmable gate arrays, vol. 180 (Springer Science & Business Media, 1992).
12. S. Wen, A. S. Rios, K. Lekkala, L. Itti, What can we learn from misclassified imagenet images?
13. O. Russakovsky, J. Deng, H. Su, J. Krause, S. Satheesh, S. Ma, Z. Huang, A. Karpathy, A. Khosla, M. Bernstein, A. C. Berg, L. Fei-Fei, ImageNet Large Scale Visual Recognition Challenge. International Journal of Computer Vision (IJCV) 115, 211-252 (2015).
14. N. P. Jouppi, C. Young, N. Patil, D. Patterson, G. Agrawal, R. Bajwa, S. Bates, S. Bhatia, N. Boden, A. Borchers, et al., Proceedings of the 44th annual international symposium on computer architecture (2017), pp. 1-12.
15. J. Lee, C. Kim, S. Kang, D. Shin, S. Kim, H.-J. Yoo, Unpu: An energy-efficient deep neural network accelerator with fully variable weight bit precision. IEEE Journal of Solid-State Circuits 54, 173-185 (2019).
16. R. Machupalli, M. Hossain, M. Mandal, Review of asic accelerators for deep neural network. Microprocessors and Microsystems 89, 104441 (2022).
17. D. Franklin, Nvidia jetson agx xavier delivers 32 teraops for new era of ai in robotics, https://developer.nvidia.com/blog/nvidia-jetson-agx-xavier-32-teraops-ai-robotics/
18. Nvidia t4, https://www. nvidia. com/en-us/data-center/tesla-t4/.
19. J. Qiu, J. Wang, S. Yao, K. Guo, B. Li, E. Zhou, J. Yu, T. Tang, N. Xu, S. Song, et al., Proceedings of the 2016 ACM/SIGDA international symposium on field-programmable gate arrays (2016), pp. 26-35.
20. X. Zhang, A. Ramachandran, C. Zhuge, D. He, W. Zuo, Z. Cheng, K. Rupnow, D. Chen, 2017 IEEE/ACM International Conference on Computer-Aided Design (ICCAD) (IEEE, 2017), pp. 894-901.
21. S. Scalera, J. Vazquez, Proceedings. IEEE Symposium on FPGAs for Custom Computing Machines (Cat. No.98TB100251) (1998), pp. 78-85.
22. S. Trimberger, D. Carberry, A. Johnson, J. Wong, Proceedings. The 5th Annual IEEE Symposium on Field-Programmable Custom Computing Machines Cat. No.97TB100186) (1997), pp. 22-28.
23. K. Vipin, S. A. Fahmy, Fpga dynamic and partial reconfiguration: A survey of architectures, methods, and applications. ACM Comput. Surv. 51(2018 ).
24. P. Babu, P. Eswaran, Reconfigurable fpga architectures: A survey and applications. Journal of The Institution of Engineers (India) Series B 102, 143-156 (2020).
25. W. Zhang, N. K. Jha, L. Shang, A hybrid nano/cmos dynamically reconfigurable system—part i: Architecture. ACM Journal on Emerging Technologies in Computing Systems (JETC) 5, 1-30 (2009).
26. T.-J. Lin, W. Zhang, N. K. Jha, Sram-based nature: A dynamically reconfigurable fpga based on 10t low-power srams. IEEE Transactions on Very Large Scale Integration (VLSI) Systems 20, 2151-2156 (2012).
27. W. Aubry, B. Le Gal, D. Negru, S. Desfarges, D. Dallet, Proceedings of the 2012 Conference on Design and Architectures for Signal and Image Processing (2012), pp. 1-7.
28. J. Delorme, A. Nafkha, P. Leray, C. Moy, 2009 International Conference on Reconfigurable Computing and FPGAs (2009), pp. 386-391.
29. M. Hosseinabady, J. L. Nunez-Yanez, Dynamic energy management of fpga accelerators in embedded systems. ACM Trans. Embed. Comput. Syst. 17(2018 ).
30. A. Rahman, V. Polavarapuv, Proceedings of the 2004 ACM/SIGDA 12th International Symposium on Field Programmable Gate Arrays, FPGA '04 (Association for Computing Machinery, New York, NY, USA, 2004), p. 23-30.
31. L. Shang, A. S. Kaviani, K. Bathala, Proceedings of the 2002 ACM/SIGDA Tenth International Symposium on Field-Programmable Gate Arrays, FPGA '02 (Association for Computing Machinery, New York, NY, USA, 2002), p. 157-164.
32. F. Li, D. Chen, L. He, J. Cong, Proceedings of the 2003 ACM/SIGDA Eleventh International Symposium on Field Programmable Gate Arrays, FPGA '03 (Association for Computing Machinery, New York, NY, USA, 2003), p. 175-184.
33. FPL '02: Proceedings of the Reconfigurable Computing Is Going Mainstream, 12th International Conference on Field-Programmable Logic and Applications (Springer-Verlag, Berlin, Heidelberg, 2002).
34. J. Greene, S. Kaptanoglu, W. Feng, V. Hecht, J. Landry, F. Li, A. Krouglyanskiy, M. Morosan, V. Pevzner, Proceedings of the 19th ACM/SIGDA international symposium on Field programmable gate arrays (2011), pp. 87-96.
35. S. Tanachutiwat, M. Liu, W. Wang, Fpga based on integration of cmos and rram. IEEE Transactions on Very Large Scale Integration (VLSI) Systems 19, 2023-2032(2010).
36. K. Huang, Y. Ha, R. Zhao, A. Kumar, Y. Lian, A low active leakage and high reliability phase change memory (pcm) based non-volatile fpga storage element. IEEE Transactions on Circuits and Systems I: Regular Papers 61, 2605-2613 (2014).
37. W. Zhao, E. Belhaire, C. Chappert, P. Mazoyer, Spin transfer torque (stt)-mram-based runtime reconfiguration fpga circuit. ACM Transactions on Embedded Computing Systems (TECS) 9, 1-16 (2009).
38. H. Mulaosmanovic, E. T. Breyer, S. D\ddot{ }unkel, S. Beyer, T. Mikolajick, S. Slesazeck, Ferroelectric field-effect transistors based on hfo2: a review. Nanotechnology (2021).
39. U. Schroeder, M. H. Park, T. Mikolajick, C. S. Hwang, The fundamentals and applications of ferroelectric hfo2. Nature Reviews Materials pp. 1-17 (2022).
40. A. I. Khan, A. Keshavarzi, S. Datta, The future of ferroelectric field-effect transistor technology. Nature Electronics 3, 588-597 (2020).
41. T. Yu, Y. Xu, S. Deng, Z. Zhao, N. Jao, Y. S. Kim, S. Duenkel, S. Beyer, K. Ni, S. George, et al., Hardware functional obfuscation with ferroelectric active interconnects. Nature communications 13, 1-11 (2022).
42. X. Chen, K. Ni, M. T. Niemier, Y. Han, S. Datta, X. S. Hu, Power and area efficient fpga building blocks based on ferroelectric fets. IEEE Transactions on Circuits and Systems I: Regular Papers 66, 1780-1793 (2019).
43. Z. Jiang, Z. Zhao, S. Deng, Y. Xiao, Y. Xu, H. Mulaosmanovic, S. Duenkel, S. Beyer, S. Meninger, M. Mohamed, R. Joshi, X. Gong, S. Kurinec, V. Narayanan, K. Ni, On the feasibility of 1t ferroelectric fet memory array. IEEE Transactions on Electron Devices (2022).
44. H. Mulaosmanovic, J. Ocker, S. M\ddot{ }uller, U. Schroeder, J. M\ddot{ }uller, P. Polakowski, S. Flachowsky, R. van Bentum, T. Mikolajick, S. Slesazeck, Switching kinetics in nanoscale hafnium oxide based ferroelectric field-effect transistors. ACS applied materials & interfaces 9, 3792-3798 (2017).
45. S. Deng, G. Yin, W. Chakraborty, S. Dutta, S. Datta, X. Li, K. Ni, 2020 IEEE Symposium on VLSI Technology (2020), pp. 1-2. 46. Predictive technology model, https://ptm.asu.edu/.
47. Y. Xiao, Y. Xu, Z. Jiang, S. Deng, Z. Zhao, A. Mallick, L. Sun, R. Joshi, X. Li, N. Shukla, V. Narayanan, K. Ni, IEEE International Electron Devices Meeting (2022).
48. J.-H. Yoon, M. Chang, W.-S. Khwa, Y.-D. Chih, M.-F. Chang, A. Raychowdhury, A
40-nm 118.44-tops/w voltage-sensing compute-in-memory rram macro with write verification and multi-bit encoding. IEEE Journal of Solid-State Circuits 57, 845-857(2022).
49. C. Lin, S. Kang, Y. Wang, K. Lee, X. Zhu, W. Chen, X. Li, W. Hsu, Y. Kao, M. Liu, W. Chen, Y. Lin, M. Nowak, N. Yu, L. Tran, 2009 IEEE International Electron Devices Meeting (IEDM) (2009), pp. 1-4.
50. K. E. Murray, O. Petelin, S. Zhong, J. M. Wang, M. ElDafrawy, J.-P. Legault, E. Sha, A. G. Graham, J. Wu, M. J. P. Walker, H. Zeng, P. Patros, J. Luu, K. B. Kent, V. Betz, Vtr 8: High performance cad and customizable fpga architecture modelling. ACM Trans. Reconfigurable Technol. Syst. (2020).
51. J. Rose, J. Luu, C. W. Yu, O. Densmore, J. Goeders, A. Somerville, K. B. Kent, P. Jamieson, J. Anderson, Proceedings of the ACM/SIGDA International Symposium on Field Programmable Gate Arrays, FPGA '12 (Association for Computing Machinery, New York, NY, USA, 2012), p. 77-86. 52. Xilinx vitis ai platform, https://www.xilinx.com/products/design-tools/ vitis/vitis-ai.html.
53. M. Trentzsch, S. Flachowsky, R. Richter, J. Paul, B. Reimer, D. Utess, S. Jansen, H. Mulaosmanovic, S. M\ddot{ }uller, S. Slesazeck, et al., 2016 IEEE International Electron Devices Meeting (IEDM) (IEEE, 2016), pp. 11-5.
54. S. Beyer, S. D\ddot{ }unkel, M. Trentzsch, J. M\ddot{ }uller, A. Hellmich, D. Utess, J. Paul, D. Kleimaier, J. Pellerin, S. M\ddot{ }uller, et al., 2020 IEEE International Memory Workshop (IMW) (IEEE, 2020), pp. 1-4.
55. S. Dutta, H. Ye, W. Chakraborty, Y.-C. Luo, M. S. Jose, B. Grisafe, A. Khanna, I. Lightcap, S. Shinde, S. Yu, S. Datta, 2020 IEEE International Electron Devices Meeting (IEDM) (2020), pp. 36.4.1-36.4.4.
56. A. J. Tan, Y.-H. Liao, L.-C. Wang, N. Shanker, J.-H. Bae, C. Hu, S. Salahuddin, Ferroelectric hfo2 memory transistors with high-κ interfacial layer and write endurance exceeding 1010 cycles. IEEE Electron Device Letters 42, 994-997 (2021). 57. Vivado design suite user guide: Partial reconfiguration, https://docs.xilinx.com/v/u/2018.1-English/ug909-vivado-partialreconfiguration (2018).

It should be understood that the disclosure of a range of values is a disclosure of every numerical value within that range, including the end points. It should also be appreciated that some components, features, and/or configurations may be described in connection with only one particular embodiment, but these same components, features, and/or configurations can be applied or used with many other embodiments and should be considered applicable to the other embodiments, unless stated otherwise or unless such a component, feature, and/or configuration is technically impossible to use with the other embodiment. Thus, the components, features, and/or configurations of the various embodiments can be combined together in any manner and such combinations are expressly contemplated and disclosed by this statement.

It will be apparent to those skilled in the art that numerous modifications and variations of the described examples and embodiments are possible considering the above teachings of the disclosure. The disclosed examples and embodiments are presented for purposes of illustration only. Other alternate embodiments may include some or all of the features disclosed herein. Therefore, it is the intent to cover all such modifications and alternate embodiments as may come within the true scope of this invention, which is to be given the full breadth thereof.

It should be understood that modifications to the embodiments disclosed herein can be made to meet a particular set of design criteria. Therefore, while certain exemplary embodiments of the compositions, materials, apparatuses, and methods of using and making the same disclosed herein have been discussed and illustrated, it is to be distinctly understood that the invention is not limited thereto but may be otherwise variously embodied and practiced within the scope of the following claims.

What is claimed is:

1. A field-programmable gate array (FPGA), comprising:
a platform including an interconnect network of configuration blocks, the configuration blocks comprising:
one or more configurable logic blocks (CLBs), each CLB including a look-up table (LUT) cell configured to perform a logic operation;
one or more connection blocks (CBs), each CB configured to connect one or more CLBs to the interconnection network;
one or more switch blocks (SBs), each SB configured to connect routes between the configuration blocks;
wherein:
one or more or the CBs includes a 1FeFET for a single configuration;
one or more of the CBs includes a 2T-2FeFET for a multiple configuration;
one or more of the CLBs includes a 1FeFET LUT cell for a single configuration; or
one or more of the CLBs includes two 1FeFET LUT cells for a multiple configuration.

2. The FPGA of claim 1, wherein:
the platform is a substrate.

3. The FPGA of claim 1, further comprising:
a configuration memory in connection with the one or more or the CBs and the one or more or the SBs.

4. The FPGA of claim 1, wherein:
the one or more CBs includes only a single 1FeFET for the single configuration.

5. The FPGA of claim 1, wherein:
the 1FeFET of the one or more CBs includes a FeFET having a source connected to an input, a drain connected to an output, and a gate connected to a word line (WL).

6. The FPGA of claim 1, wherein:
the 2T-2FeFET architecture includes two parallel branches.

7. The FPGA of claim 1, wherein:
the 2T-2FeFET architecture includes:
a first MOSFET having a source (S1), a gate (G1), and a drain (D1);
a second MOSFET having a source (S2), a gate (G2), and a drain (D2);
a first FeFET having a source (S3), a gate (G3), and a drain (D3);
a second FeFET having a source (S4), a gate (G4), and a drain (D4);
each of S1 and S3 is connected to an input;
D1 is connected to S2;
each of D2 and D4 is connected to an output; and
D3 is connected to S4.

8. The FPGA of claim 1, wherein:
the 1FeFET LUT cell for the single configuration includes plural memory cells connected to a multiplexer; and
high-V_{TH}/low-V_{TH} states of the 1FeFET facilitates storage of bits ‘1’/‘0’ in the plural memory cells.

9. The FPGA of claim 1, wherein:
the two 1FeFET LUT cells for the multiple configuration includes:
a first 1FeFET LUT cell having plural memory cells connected to a first multiplexer, wherein high-V_{TH}/low-V_{TH} states of the 1FeFET facilitates storage of bits ‘1’/‘0’ in the plural memory cells;
a second 1FeFET LUT cell having plural memory cells connected to a second multiplexer, wherein high-V_{TH}/low-V_{TH} states of the 1FeFET facilitates storage of bits ‘1’/‘0’ in the plural memory cells;
the one or more of the CLBs includes a third multiplexer, the third multiplexer connected to each of the first multiplexer and the second multiplexer.
